(19) United States
(12) Patent Application Publication
(10) Pub. No.: US 2025/0221185 A1
(43) Pub. Date: Jul. 3, 2025

(54) LIGHT EMITTING DISPLAY APPARATUS

(71) Applicant: LG Display Co., Ltd., Seoul (KR)

(72) Inventors: Inae Choi, Paju-si (KR); Sejong Seong, Paju-si (KR); Donggu Kim, Paju-si (KR)

(73) Assignee: LG Display Co., Ltd., Seoul (KR)

(21) Appl. No.: 18/988,101

(22) Filed: Dec. 19, 2024

(30) Foreign Application Priority Data
Dec. 28, 2023 (KR) 10-2023-0194556

(51) Int. Cl. H10K 59/124; H10K 59/122

(52) U.S. Cl. CPC H10K 59/124; H10K 59/122

(57) ABSTRACT

A light emitting display apparatus includes a substrate and a plurality of pixels each including a plurality of subpixels on the substrate. Each of the plurality of subpixels includes a light-transmissive part, a first emission part at a first side of the light-transmissive part, and a second emission part at a second side of the light-transmissive part different from the first side of the light-transmissive part. Each of the first emission part and the second emission part is inclined from the light-transmissive part.

### CROSS-REFERENCE TO RELATED APPLICATION

This application claims the benefit of and priority to Korean Patent Application No. 10-2023-0194556, filed on Dec. 28, 2023, the entirety of each which is hereby incorporated by reference for all purposes as if fully set forth herein.

### BACKGROUND

### Technical Field

The present disclosure relates to a light emitting display apparatus which displays an image.

### Description of the Related Art

A light emitting display apparatus exhibits a high response speed while maintaining low power consumption. Unlike a liquid crystal display apparatus, the light emitting display apparatus is a self-emissive display device and does not require a separate light source. Thus, there is typically no problem with the viewing angle. Accordingly, a light emitting display apparatus has received attention as a next generation flat panel display apparatus. For example, a light emitting display apparatus displays an image through light emission of a light emitting device including an emission layer interposed between two electrodes.

Recently, research for transparent display apparatuses enabling a user (or a viewer) to see a thing or a background located at a rear surface of a display apparatus are being actively done. Transparent display apparatuses may be categorized into light-transmissive parts which intactly transmit light incident thereon and emission parts which emit light. A user (or a viewer) may see a thing or a background, located at a rear surface of a transparent display apparatus, through the light-transmissive parts.

### SUMMARY

Accordingly, an aspect of the present disclosure is directed to providing a light emitting display apparatus that substantially obviates one or more problems due to limitations and disadvantages of the related art.

An aspect of the present disclosure is directed to providing a light emitting display apparatus including a light-transmissive part.

Another aspect of the present disclosure is directed to providing a light emitting display apparatus which may include a light-transmissive part and may implement a stereoscopic image.

The aspects of the present disclosure are not limited to the aforesaid, but other aspects not described herein will be clearly understood by those skilled in the art from the description herein.

To achieve these and other advantages and aspects of the present disclosure, as embodied and broadly described herein, in one or more aspects, a light emitting display apparatus comprises a substrate, and a plurality of pixels each including a plurality of subpixels on the substrate, each of the plurality of subpixels comprises a light-transmissive part, a first emission part at a first side of the light-transmissive part, and a second emission part at a second side of the light-transmissive part different from the first side of the light-transmissive part. Each of the first emission part and the second emission part is inclined from the light-transmissive part.

According to one or more embodiments of the present disclosure, the second emission part is at the second side of the light-transmissive part which is opposite to the first side of the light-transmissive part, and each of the first emission part and the second emission part is configured to be inclined with respect to the substrate.

According to one or more embodiments of the present disclosure, each of the plurality of subpixels comprises a pixel circuit connected to the first emission part and the second emission part, a protection layer covering the pixel circuit, a pattern part over the protection layer, and a light emitting device over the pattern part. The first emission part and the second emission part are configured at the pattern part.

According to one or more embodiments of the present disclosure, the pattern part comprises an upper surface, a first slope surface at a first side of the upper surface, and a second slope surface at a second side different from the first side of the upper surface. The light-transmissive part is at the upper surface of the pattern part, and the first emission part is at the first slope surface of the pattern part. The second emission part is at the second slope surface of the pattern part.

A light emitting display apparatus according to one or more embodiments of the present disclosure comprises a substrate, and a plurality of pixels including a plurality of subpixels over the substrate, each of the plurality of subpixels comprises a light-transmissive part, and a plurality of emission part disposed adjacent to the light-transmissive part and inclined with respect to the substrate.

According to one or more embodiments of the present disclosure, the plurality of emission part comprises a first slope emission part at a first side of the light-transmissive part, and a second slope emission part at a second side of the light-transmissive part different from the first side of the light-transmissive part. Each of the first slope emission part and the second slope emission part is inclined with respect to the substrate.

According to one or more embodiments of the present disclosure, each of the plurality of subpixels comprises a pixel circuit connected to the first slope emission part and the second slope emission part, a protection layer covering the pixel circuit, a pattern part over the protection layer, and a light emitting device over the pattern part. The first slope emission part and the second slope emission part are configured at the pattern part.

According to one or more embodiments of the present disclosure, the pattern part comprises an upper surface, a first slope surface at a first side of the upper surface, and a second slope surface at a second side different from the first side of the upper surface. The light-transmissive part is at the upper surface of the pattern part, the first slope emission part is at the first slope surface of the pattern part, and the second slope emission part is at the second slope surface of the pattern part.

According to one or more embodiments of the present disclosure, the upper surface of the pattern part comprises a flat surface, and/or an angle between an upper surface of the protection layer and each of the first slope surface and the second slope surface of the pattern part is an acute angle.

According to one or more embodiments of the present disclosure, the pattern part comprises a first pattern layer over the protection layer, a groove portion at the first pattern layer and overlapping the light-transmissive part, and a second pattern layer at the groove portion. The upper surface of the pattern part comprises an upper side surface of the first pattern layer and an upper side surface of the second pattern layer, and the first pattern layer comprises the first slope surface and the second slope surface.

The light emitting display apparatus according to one or more embodiments of the present disclosure may include a light-transmissive part, thereby implementing a transparent display apparatus.

The light emitting display apparatus according to one or more embodiments of the present disclosure may include a light-transmissive part and may display a stereoscopic image, thereby implementing a transparent display apparatus or a transparent stereoscopic image display apparatus. For example, the light emitting display apparatus (or the transparent display apparatus or the transparent stereoscopic image display apparatus) according to one or more embodiments of the present disclosure may implement (or display) a stereoscopic image based on a light field mode (or a light field type).

Other aspects, features and advantages of the present disclosure are set forth in the present disclosure and will also be apparent from the present disclosure or may be learned by practice of the inventive concepts provided herein. Other aspects, features and advantages of the present disclosure may be realized and attained by the descriptions provided in the present disclosure, including the claims and the drawings.

Furthermore, other devices, methods, features and advantages will be, or will become, apparent to one with skill in the art upon examination of the drawings and detailed description herein. It is intended that all such devices, methods, features and advantages be included within this description, be within the scope of the present disclosure, and be protected by the following claims and their equivalents. Nothing in this section should be taken as a limitation on the claims. Further aspects and advantages are discussed below in conjunction with embodiments of the disclosure.

It is to be understood that both the foregoing description and the following description of the present disclosure are by way of example and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure and together with the description serve to explain principles of the disclosure.

FIG. 1 is a view schematically illustrating a light emitting display apparatus according to an example embodiment of the present disclosure.

FIG. 2 is a plan view illustrating an example of one pixel illustrated in FIG. 1.

FIG. 3 is an equivalent circuit view illustrating a first subpixel illustrated in FIG. 2.

FIG. 4 is an example cross-sectional view taken along line I-I′ illustrated in FIG. 2.

FIG. 5 is an example cross-sectional view taken along line II-II′ illustrated in FIG. 2.

FIG. 6 is an enlarged view of part “A” illustrated in FIG. 5.

FIG. 7 is another example cross-sectional view taken along line II-II′ illustrated in FIG. 2.

FIG. 8 is another example cross-sectional view taken along line II-II′ illustrated in FIG. 2.

FIG. 9 is another example cross-sectional view taken along line II-II′ illustrated in FIG. 2.

FIG. 10 is a plan view illustrating another example of one pixel illustrated in FIG. 1.

FIG. 11 is an equivalent circuit view illustrating a first subpixel illustrated in FIG. 10.

FIG. 12 is an example cross-sectional view taken along line III-III′ illustrated in FIG. 10.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and convenience.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, where the detailed description of the relevant known function or configuration may unnecessarily obscure important or significant aspects of the present disclosure, the detailed description may be omitted.

In a case where a term like ‘comprise’, ‘have’, or ‘include’ is used to describe a feature in the present specification, another part may be added unless a more limiting term like ‘only˜’ is used. The terms of a singular form may include plural forms, and vice versa, unless referred to the contrary.

In construing an element, the element is to be construed as including an error range although there is no explicit description.

Where a position relationship, for example, between two parts is described as ‘on˜’, ‘over˜’, ‘under˜’, ‘next˜’, or the like, one or more other parts may be disposed between the two parts unless a more limiting term like ‘just’ or ‘direct’ is used.

Where a temporal relationship, for example, is described as “after,” “subsequent,” “next,” “before,” or the like, a case which is not continuous may be included, unless a more limiting term like “just” or “direct” is used.

It will be understood that, although the terms “first,” “second,” etc., may be used herein to describe various elements, these elements should not be limited by these terms. These terms are only used to refer to one element separately from another. For example, a first element could be termed a second element, and, similarly, a second element could be termed a first element, without departing from the scope of the present disclosure.

In describing elements of the present disclosure, the terms “first,” “second,” “A,” “B,” “(a),” “(b),” or the like may be used. These terms are intended to identify the corresponding element(s) separately from the other element(s), and these are not used to define the essence, basis, order, or number of the elements. For the expression that an element is “connected,” “coupled,” or “contact,” to another element, the element may not only be directly connected, coupled, or contacted to another element, but also be indirectly connected, coupled, or contacted to another element with one or more intervening elements interposed between the elements, unless otherwise specified.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

“X-axis direction”, “Y-axis direction”, and “Z-axis direction” should not be construed by a geometric relation only of a mutual vertical relation and may have broader directionality within the range that elements of the present disclosure may act functionally.

Features of various embodiments of the present disclosure may be partially or entirely coupled to or combined with each other and may be operated in various coordination with each other and driven technically as those skilled in the art may sufficiently understand. The embodiments of the present disclosure may be carried out independently from each other or may be carried out together in co-dependent relationship.

Hereinafter, example embodiments of a light emitting display apparatus according to the present disclosure will be described in detail with reference to the accompanying drawings. For convenience of description, a scale of each of elements illustrated in the accompanying drawings differs from a real scale, and thus, is not limited to a scale illustrated in the drawings.

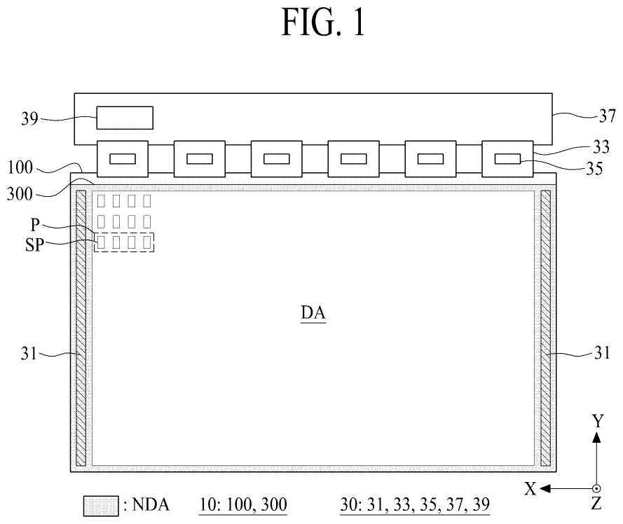

FIG. 1 is a view schematically illustrating a light emitting display apparatus according to an example embodiment of the present disclosure.

As shown in FIG. 1, a light emitting display apparatus according to an embodiment of the present disclosure may be a flexible light emitting display apparatus, an organic light emitting display apparatus, a flexible organic light emitting display apparatus, or a light field display apparatus, and the like, but embodiments of the present disclosure are not limited thereto. For example, the light emitting display apparatus according to an embodiment of the present disclosure may include a set electronic apparatus or a set device (or a set apparatus) such as a notebook computer, a television, a computer monitor, an equipment apparatus including an automotive apparatus or another type apparatus for vehicles, or a mobile electronic apparatus such as a smartphone or an electronic pad, which is a complete product (or a final product) including a display panel.

A light emitting display apparatus or a light emitting display panel according to one or more embodiments of the present disclosure may be applied to or included in any electronic apparatuses. The light emitting display apparatus or the light emitting display panel according to one or more embodiments of the present disclosure may be applied to or included in mobile apparatuses, video phones, smart watches, watch phones, wearable apparatuses, foldable apparatuses, rollable apparatuses, bendable apparatuses, flexible apparatuses, curved apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, TVs, game machines, notebook computers, monitors, cameras, camcorders, and home appliances, or the like. In addition, the light emitting display apparatus or the light emitting display panel according to one or more embodiments of the present disclosure may be applied to or included in wall paper display apparatuses, signage apparatuses, window-type display apparatuses, smart show windows, smart mirrors, or bidirectional information transfer apparatuses, transparent display apparatuses, stereoscopic image display apparatuses, or transparent stereoscopic image display apparatuses, but embodiments of the present disclosure are not limited thereto.

The light emitting display apparatus according to an embodiment of the present disclosure may include a display panel 10.

The display panel 10 may include a substrate 100. The substrate 100 includes a thin film transistor, and the substrate 100 may be a first substrate, a base substrate, a lower substrate, a transparent glass substrate, a transparent plastic substrate, or a base member.

The display panel 10 or the substrate 100 may include a display area (or a display portion) DA and a non-display area (or a non-display portion). The display area DA is an area in which an image is displayed, and may be disposed at a central area of the display panel 10. The non-display area is an area in which an image is not displayed, and may be configured to surround the display area DA.

The display panel 10 includes a plurality of pixels P provided (or configured) on the substrate 100. The display panel 10 or the substrate 100 includes a plurality of pixels P provided (or configured) at the display area DA. Each of the plurality of pixels P may include a plurality of subpixels SP. Each of the plurality of pixels P may be disposed (or arranged) along a first direction (X) and a second direction Y which intersects with the first direction X. For example, in the present disclosure, the first direction X may be an X-axis direction or a horizontal direction of the display panel 10 or the substrate 100. The second direction Y may be a Y-axis direction or a vertical direction of the display panel 10 or the substrate 100.

Each of the plurality of subpixels SP may be defined as a point light source emitting light. At least three subpixels SP disposed to be adjacent to each other among the plurality of subpixels SP may configure a pixel (or a unit pixel) P. According to an embodiment, at least four subpixels, which are provided to emit different colors and disposed to be adjacent to one another among the plurality of subpixels SP may configure one pixel P. One pixel P may include a red subpixel (or a first subpixel), a blue subpixel (or a second subpixel), a white subpixel (or a third subpixel), and a green subpixel (or a fourth subpixel), but is not limited thereto. According to another embodiment, one pixel P may include three subpixels SP, which are provided to emit different colors and disposed to be adjacent to one another among the plurality of subpixels SP. For example, one pixel P may include a red subpixel (or a first subpixel), a blue subpixel (or a second subpixel), and a green subpixel (or a third subpixel).

Each of the plurality of subpixels SP according to an embodiment of the present disclosure may include a plurality of emission parts (or emission areas). For example, each of the plurality of subpixels SP may include a light-transmissive part and a plurality of emission parts. For example, each of the plurality of subpixels SP may include a light-transmissive part and a plurality of emission parts which are disposed adjacent to the light-transmissive part and are inclined with respect to the substrate 100. For example, each of the plurality of subpixels SP may include a light-transmissive part (or a light-transmissive area), a first emission part (or a first view emission part) which is at a first side of the light-transmissive part, and a second emission part (or a second view emission part) which is at a second side, which is different from or opposite to the first side, of the light-transmissive part.

According to an embodiment of the present disclosure, the light-transmissive part may be disposed at a first region (or a middle region) of each of the plurality of subpixels SP. The first emission part may be disposed at a second region (or one side region or one edge region of the first region) of each of the plurality of subpixels SP. The second emission part may be disposed at a third region (or the other side region or the other edge region of the first region) of each of the plurality of subpixels SP. For example, the first emission part and the second emission part may be disposed (or configured) in parallel with the light-transmissive part therebetween.

According to an embodiment of the present disclosure, an angle of light emitted from each of the first emission part and the second emission part may differ from an angle of light transmitted passing through the light-transmissive part. For example, a light-transmissive surface of the light-transmissive part may be parallel to the substrate 100, and a light extraction surface (or an emission surface) of each of the first emission part and the second emission part may be inclined or sloped with respect to the substrate 100. For example, the light-transmissive part may be configured to transmit light in a direction perpendicular to a surface of the substrate 100, and the first emission part and the second emission part may be configured to output light in a direction which is inclined with respect to the surface of the substrate 100.

According to an embodiment of the present disclosure, each of the first emission part and the second emission part may be inclined or sloped with respect to the light-transmissive part. Each of the first emission part and the second emission part may be configured to be inclined with respect to the substrate 100. For example, the light-transmissive part may include a flat structure which is disposed (or configured) over a flat surface, and the first emission part and the second emission part may include a slope structure or a tilt structure, which is disposed (or configured) over a slope surface inclined with respect to the flat surface. For example, the first emission part and the second emission part may include a slope structure or a tilt structure, which is disposed (or configured) over the slope surface inclined with respect to the substrate 100.

The light emitting display apparatus according to an embodiment of the present disclosure may include the light-transmissive part and the plurality of emission parts, which are configured at each of a plurality of subpixels SP, and thus, a user (or a viewer) may see an image displayed by the plurality of emission parts and may see a thing or a background, disposed at a rear surface of a transparent display apparatus, through the light-transmissive parts. In addition, the light emitting display apparatus according to an embodiment of the present disclosure may display a stereoscopic image through the individual light emission of each of the main emission part and the plurality of sub emission parts each configured in each of the plurality of subpixels SP, and thus, may implement (or display) a stereoscopic image (for example, a stereoscopic image of a light field mode (or a light field type)) or may provide a stereoscopic image to a user (or a viewer). Accordingly, the light emitting display apparatus according to an embodiment of the present disclosure may implement a transparent display apparatus or a transparent stereoscopic image display apparatus.

The display panel 10 may further include a counter substrate (or opposite substrate) 300. The counter substrate 300 may be configured to encapsulate (or seal) the display area DA disposed over the substrate 100. For example, the counter substrate 300 may be opposite-bonded to the substrate 100 using an adhesive member (or transparent adhesive). The counter substrate 300 may be an upper substrate, a second substrate, or an encapsulation substrate. For example, the counter substrate 300 may include a transparent material for enabling the light-transmissive part to transmit light. For example, the counter substrate 300 may be configured as a transparent glass material or a transparent plastic material.

The light emitting display apparatus according to an embodiment of the present disclosure may further include a driving circuit part 30.

The driving circuit part 30 may be configured to display an image corresponding to image data supplied from a display driving system (or a host system) in each pixel P.

The driving circuit part 30 according to an embodiment of the present disclosure may include a gate driving circuit 31, a plurality of flexible circuit films 33, a plurality of driving integrated circuits (ICs) 35, a printed circuit board (PCB) 37, and a control circuit part 39.

The gate driving circuit 31 may be disposed (or configured) at a non-display area NDA of the substrate 100 and may be connected to the plurality of subpixels SP. The gate driving circuit 31 according to an embodiment of the present disclosure may be integrated with one non-display area or both non-display area of the substrate 100 in accordance with a manufacturing process of a thin film transistor, and may be connected to the plurality of subpixels SP. For example, the gate driving circuit 31 may include a generally known shift register.

Each of the plurality of flexible circuit films 33 may be configured to be electrically connected between the PCB 37 and a pad part provided at one edge portion of the substrate 100. Each of the plurality of flexible circuit film 31 according to an embodiment of the present disclosure may be a tape carrier package (TCP) or a chip-on film (COF), but is not limited thereto.

Each of the plurality of driving ICs 35 may be individually mounted on (or at) a corresponding flexible circuit film 33 of the plurality of flexible circuit films 33. Each of the plurality of driving ICs 35 may receive subpixel data and a data control signal provided from the control circuit part 39, convert the subpixel data into a subpixel-based analog data voltage according to the data control signal, and supply the analog data voltage to a corresponding subpixel SP. For example, each of the plurality of driving ICs 35 may generate a plurality of grayscale voltages by using a plurality of reference gamma voltages provided from the PCB 37 and may select, as a subpixel-based data voltage, a grayscale voltage corresponding to the subpixel data from among the plurality of grayscale voltages to output the selected data voltage.

Each of the plurality of driving ICs 35 may sequentially sense a characteristic value of a driving thin film transistor configured at the subpixel SP through the plurality of reference voltage lines disposed (or configured) on the substrate 100 to be connected to each of the plurality of subpixels SP, generate sensing raw data corresponding to a sensing value, and provide the sensing raw data to the control circuit part 39.

The PCB 37 may be electrically connected to each of the plurality of flexible circuit films 33. The PCB 37 may serve to transmit a signal and a voltage between elements of the driving circuit part 30.

The control circuit part 39 may be mounted on the PCB 37 and may receive image data and a timing synchronization signal provided from the display driving system through a user connector disposed at the PCB 37. Alternatively, the control circuit part 39 may not be mounted on the PCB 37 and may be configured in the display driving system or may be mounted on a separate control board connected between the PCB 37 and the display driving system.

The control circuit part 39 may generate each of the data control signal and a gate control signal based on the timing synchronization signal, control a driving timing of each of the driving ICs 35 based on the data control signal, and control a driving timing of the gate driving circuit 31 based on the gate control signal. For example, the timing synchronization signal may include a vertical synchronization signal, a horizontal synchronization signal, a data enable signal, and a main clock (or a dot clock).

The control circuit part 39 may align the image data based on the timing synchronization signal so as to match a pixel arrangement structure disposed at the display area DA to generate pixel data and may be configured to provide the generated pixel data to each of the plurality of driving ICs 35.

According to an embodiment of the present disclosure, when the pixel P includes a white subpixel emitting white light, the control circuit part 39 may extract white pixel data based on the digital image data (for example, red input data, green input data, and blue input data which are to be respectively supplied to corresponding pixels P), reflect offset data based on the extracted white pixel data in each of the red input data, the green input data, and the blue input data to calculate red pixel data, green pixel data, and blue pixel data, and align the calculated red pixel data, green pixel data, and blue pixel data and the white pixel data according to the pixel arrangement structure to supply aligned pixel data to each of the driving ICs 35.

According to an embodiment of the present disclosure, the control circuit part 39 may generate subpixel-based subpixel data corresponding to each of the plurality of subpixels SP to supply to each of the plurality of driving ICs 35, based on red input data, green input data, and blue input data which are to be respectively supplied to the plurality of subpixels SP. Each of the plurality of driving ICs 35 may convert the subpixel-based subpixel data, provided from the control circuit part 39, into a subpixel-based data voltage to supply to a corresponding subpixel SP.

According to another embodiment of the present disclosure, the control circuit part 39 may generate a plurality of emission data corresponding to each of the plurality of subpixels SP to supply to each of the plurality of driving ICs 35, based on red input data, green input data, and blue input data which are to be respectively supplied to the plurality of subpixels SP. For example, the control circuit part 39 may generate first field data (or a first emission data or a first viewing data) and second field data (or a second emission data or a second viewing data) respectively corresponding to the plurality of subpixels SP to supply to each of the plurality of driving ICs 35. Each of the plurality of driving ICs 35 may respectively convert subpixel-based first field data and second field data provided from the control circuit part 39 into a first field data voltage (or a first sub field data voltage or a first viewing data voltage), and a second field data voltage (or a second sub field data voltage or a second viewing data voltage) to supply to a corresponding subpixel SP.

According to another embodiment of the present disclosure, the control circuit part 39 may generate subpixel-based subpixel data corresponding to each of the plurality of subpixels SP to supply to each of the plurality of subpixels SP, based on a normal driving mode of the light emitting display apparatus. In addition, the control circuit part 39 may generate the first field data and the second field data corresponding to each of the plurality of subpixels SP to supply to each of the plurality of driving ICs 35, based on a light field driving mode (or a stereoscopic image display mode) of the light emitting display apparatus.

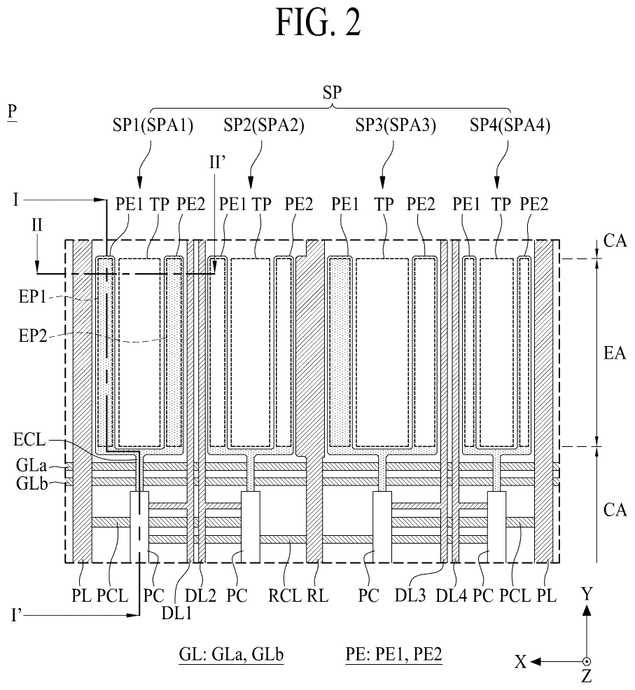

FIG. 2 is a plan view illustrating an example of one pixel illustrated in FIG. 1.

As shown in FIGS. 1 and 2, in a light emitting display apparatus (or light emitting display panel) according to an embodiment of the present disclosure, each of a plurality of pixels P may include a plurality of subpixels SP1 to SP4.

Each of the plurality of pixels P may include first to fourth subpixels SP1 to SP4 adjacent to one another along a first direction X. For example, each of the plurality of pixels P may include a red subpixel SP1, a blue subpixel SP2, a white subpixel SP3, and a green subpixel SP4, but embodiments according to the present disclosure are not limited thereto. For example, each of the plurality of pixels P may include a red subpixel SP1, a white subpixel SP2, a blue subpixel SP3, and a green subpixel SP4, but embodiments according to the present disclosure are not limited thereto. Each of the first to fourth subpixels SP1 to SP4 may be configured to have different sizes (or areas) from each other.

Each of the plurality of pixels P may be connected to a gate line GL, a driving voltage line PL, first to fourth data lines DL1 to DLA, and a reference voltage line RL.

The gate line GL may be disposed (or configured) in parallel to the first direction X. The gate line GL may be configured to be connected to the plurality of subpixels SP1 to SP4 disposed along the first direction X in common. For example, the gate line GL may include first and second gate lines GLa and GLb. The first and second gate lines GLa and GLb may extend long along the first direction X and may be disposed (or configured) to be spaced apart from each other along a second direction Y. For example, the first and second gate lines GLa and GLb may be configured to be connected to the plurality of subpixels SP1 to SP4 disposed along the first direction X in common. The gate line GL may be electrically connected to the gate driving circuit 31 and may be configured to supply a gate signal, supplied from the gate driving circuit 31, to the plurality of subpixels SP1 to SP4.

The driving voltage line PL may be disposed (or configured) in parallel to the second direction Y. The driving voltage line PL may be configured to be connected to the plurality of subpixels SP1 to SP4 in common. For example, the display panel 10 may include a plurality of driving voltage lines PL which extend long along the second direction Y and are spaced apart from one another along the first direction X. The plurality of pixels P may be disposed between the plurality of driving voltage lines PL.

The first to fourth data lines DL1 to DL4 may extend long along the second direction Y and may be disposed (or configured) to be spaced apart from each other along the first direction X. For example, the first to fourth data lines DL1 to DL4 may be configured to be electrically connected to different subpixels SP1 to SP4 in the pixel P. According to an embodiment, the first data line DL1 and the second data line DL2 may be disposed in parallel between the first subpixel SP1 and the second subpixel SP2. The third data line DL3 and the fourth data line DL4 may be disposed in parallel between the third subpixel SP3 and the fourth subpixel SP4. The first to fourth data lines DL1 to DL4 may be electrically connected to the plurality of driving ICs 35 and may be configured to supply a data signal, supplied from the plurality of driving ICs 35, to the plurality of subpixels SP1 to SP4.

The reference voltage line RL may be disposed (or configured) to extend long along the second direction Y. The reference voltage line RL may be configured to be connected to the plurality of subpixels SP1 to SP4 in common. According to an embodiment, the reference voltage line RL may be disposed between the second subpixel SP2 and the third subpixel SP3, but is not limited thereto. The reference voltage line RL may be used as a sensing line for sensing a change of characteristics of a driving thin film transistor and/or a change of characteristics of the light emitting device, which is disposed in the subpixels SP1 to SP4, from the outside in a sensing driving mode of the pixel P.

Each of the first to fourth subpixels SP1 to SP4 may be configured to display images in accordance with gate signals supplied from the gate lines GL adjacent thereto and data signals supplied from the data lines DL adjacent thereto.

Each of the first to fourth subpixels SP1 to SP4 may include an emission area EA and a circuit area CA. The emission area EA may be disposed at one side (or an upper side) of a subpixel area SPA1 to SPA4. The emission area EA of each of the first to fourth subpixels SP1 to SP4 may have different sizes (or areas) from each other, but is not limited thereto. For example, the emission area EA may be an opening area (or an opening area region) or a light emitting area (or a light emitting region). According to an embodiment, the emission area EA of the third subpixel SP3 may have the greatest size of the emission area EA of the first to fourth subpixel SP1 to SP4, the emission area EA of the fourth subpixel SP4 may have the smallest size of the emission area EA of the first to fourth subpixel SP1 to SP4, and the emission area EA of the first subpixel SP1 may have a size which is smaller than the emission area EA of the third subpixel SP3 and is greater than the emission area EA of each of the second and fourth subpixels SP2 and SP4. In addition, the emission area EA of the second subpixel SP2 may have a size which is greater than the emission area EA of the fourth subpixel SP4.

The circuit area CA of each of the first to fourth subpixels SP1 to SP4 may be spatially separated from the emission area EA within the subpixel area SPA1 to SPA4. For example, the circuit area CA may be disposed at the other side (or a lower side) of the subpixel area SPA1 to SPA4, but is not limited thereto. For example, at least a portion of the circuit area CA may overlap with the emission area EA within the subpixel area SPA1 to SPA4. For example, the circuit area CA may overlap an entire emission area EA within the subpixel area SPA1 to SPA4, or may be disposed under (or below) the emission area EA within the subpixel area SPA1 to SPA4. For example, the circuit area CA may be a non-emission area (or a non-emission region) or a non-opening area (or a non-opening region).

Each of the first to fourth subpixels SP1 to SP4 according to an embodiment of the present disclosure may include a light-transmissive part TP and a plurality of emission parts EP1 and EP2, which are at an emission region EA of each of subpixel areas SPA1 to SPA4. The emission region EA of each of the first to fourth subpixels SP1 to SP4 may include a plurality of emission parts EP1 and EP2.

The light-transmissive part TP may have a size (or an area) which differs from that of each of the plurality of emission parts EP1 and EP2. The light-transmissive part TP may have a size (or an area) which is greater than that of each of the plurality of emission parts EP1 and EP2. The plurality of emission parts EP1 and EP2 may have the same size (or area), or may have different sizes (or areas).

The plurality of emission parts EP1 and EP2 may be configured to be inclined from the light-transmissive part TP. The plurality of emission parts EP1 and EP2 may be configured to be inclined with respect to one or more of the light-transmissive part TP and the substrate 100. For example, the plurality of emission parts EP1 and EP2 may be configured to be inclined at an obtuse angle from the light-transmissive part TP or to be inclined at an acute angle with respect to the substrate 100.

Light output angles in partial regions of the light-transmissive part TP and the plurality of emission parts EP1 and EP2 may differ. A light output angle in the light-transmissive part TP may differ from a light output angle in the plurality of emission parts EP1 and EP2. For example, the light-transmissive part TP may be configured to transmit (or output) light in a direction perpendicular to a surface of the substrate 100 and the plurality of emission parts EP1 and EP2 may be configured to output light in a direction which is inclined with respect to the surface of the substrate 100.

Each of the first to fourth subpixels SP1 to SP4 according to an embodiment of the present disclosure may include a light-transmissive part TP, a first emission part (or a first light emitting part or a first light emitting portion) EP1, and a second emission part (or a second light emitting part or a second light emitting portion) EP2. For example, each of the first to fourth subpixels SP1 to SP4 may include the light-transmissive part TP disposed at a first region of the subpixel regions SPA1 to SPA4, the first emission part EP1 disposed at a second region of the subpixel regions SPA1 to SPA4, and the second emission part EP2 disposed at a third region of the subpixel regions SPA1 to SPA4. For example, in each of the subpixel regions SPA1 to SPA4, the first region may be a center region or a middle region, the second region may be one edge region, a first edge region, or one side region of the first region, and the third region may be the other edge region, a second edge region, or the other side region of the first region.

Each of the light-transmissive part TP, the first emission part EP1, and the second emission part EP2 may have a width parallel to the first direction X and a length parallel to the second direction Y. For example, a short side of each of the light-transmissive part TP, the first emission part EP1, and the second emission part EP2 may be parallel to a horizontal direction of the display panel 10 or the substrate 100. A long side of each of the light-transmissive part TP, the first emission part EP1, and the second emission part EP2 may be parallel to a vertical direction of the display panel 10 or the substrate 100. The light-transmissive part TP, the first emission part EP1, and the second emission part EP2 may be disposed (or arranged or configured) in parallel. The light-transmissive part TP may be disposed between the first emission part EP1 and the second emission part EP2. The first emission part EP1 and the second emission part EP2 may be disposed (or configured) in parallel with the light-transmissive part TP therebetween and may be disposed (or configured) to be inclined with respect to the substrate 100.

Some of the light-transmissive part TP, the first emission part EP1, and the second emission part EP2 may have different sizes (or areas). For example, the light-transmissive part TP may have a size (or area) which is greater than each of the plurality of emission parts EP1 and EP2. The plurality of emission parts EP1 and EP2 may have a same size (or area) or different sizes (or areas), but is not limited thereto. For example, the light-transmissive part TP may have a size which is equal to a sum of a size of the first emission part EP1 and a size of the second emission part EP2, or may have a size which is greater than the sum of a size of the first emission part EP1 and a size of the second emission part EP2.

According to an embodiment of the present disclosure, the light-transmissive part TP may be disposed (or configured) to face or be parallel to a surface (or front surface or light output surface) of the substrate 100. A light-transmissive surface of the light-transmissive part TP may be disposed (or configured) to face or be parallel to the surface of the substrate 100. The light-transmissive part TP may be configured to transmit light in a direction perpendicular to the surface (or front surface or light output surface) of the substrate 100.

Each of the first and second emission parts EP1 and EP2 may be inclined or sloped from the light-transmissive part TP. Each of the first emission part EP1 and the second emission part EP2 may be inclined or sloped with respect to the substrate 100. Each of the first and second emission parts EP1 and EP2 may be sloped or inclined by a same angle with respect to the light-transmissive part TP and/or the substrate 100. The light extraction surface (or emission surface) of each of the first and second emission parts EP1 and EP2 may be inclined or sloped from the light extraction surface (or emission surface) of the light-transmissive part TP. The light extraction surface (or emission surface) of each of the first and second emission parts EP1 and EP2 may be inclined or sloped with respect to the surface (or front surface or light output surface) of the substrate 100. Each of the first and second emission parts EP1 and EP2 may be configured to output light in a direction which is sloped or inclined with respect to the surface (or front surface or light output surface) of the substrate 100.

According to an embodiment of the present disclosure, the light-transmissive part TP may be a transmissive part, a light-transmissive region, a flat light-transmissive region, or a center light-transmissive part, a transparent part, a transparent region, a flat transparent part, a flat transparent region, or a center transparent part. The first emission part EP1 may be a first sub-emission part, a first side emission part, a first slope emission part, a first viewing emission part, or a first edge emission part. The second emission part EP2 may be a second sub-emission part, a second side emission part, a second slope emission part, a second viewing emission part, or a second edge emission part.

According to an embodiment of the present disclosure, each of the plurality of or first to fourth subpixels SP1 to SP4 may include a pixel electrode PE which is disposed at each of the subpixel regions SPA1 to SPA4.

The pixel electrode PE may include a plurality of or first and second pixel electrodes PE1 and PE2 which are disposed in parallel in (or within) the subpixel regions SPA1 to SPA4. The first and second emission parts EP1 and EP2 may be implemented (or configured) by the first and second pixel electrodes PE1 and PE2. For example, the first emission part EP1 may correspond to the first pixel electrode PE1, and the second emission part EP2 may correspond to the second pixel electrode PE2.

The first and second pixel electrodes PE1 and PE2 may be separated or spaced apart from one another by the light-transmissive part TP, in (or within) the emission area EA of each of the subpixel regions SPA1 to SPA4. For example, the first pixel electrode PE1 and the second pixel electrode PE2 may be disposed (or configured) in parallel with each other with the light-transmissive part TP therebetween.

One end of each of the first and second pixel electrodes PE1 and PE2 may be electrically connected to an electrode connection line ECL. For example, each of the first and second pixel electrodes PE1 and PE2 may protrude or extend from the electrode connection line ECL, in (or within) the subpixel regions SPA1 to SPA4. The electrode connection line ECL may be connected to the one end of each of the first and second pixel electrodes PE1 and PE2 in common. For example, the electrode connection line ECL may be disposed (or configured) at the circuit area CA.

Each of the plurality of or first to fourth subpixels SP1 to SP4 may include a pixel circuit PC which is disposed (or configured) over the substrate 100 of the circuit area CA.

The pixel circuit PC configured at each of the plurality of or first to fourth subpixels SP1 to SP4 may be configured to supply a data current to the plurality of or first and second pixel electrodes PE1 and PE2 disposed at corresponding subpixels SP1 to SP4. For example, the pixel circuit PC may be configured to simultaneously supply the data current to the plurality of or first and second pixel electrodes PE1 and PE2.

The pixel circuit PC may be configured to be connected to a corresponding gate line GL, a corresponding driving voltage line PL, corresponding data lines DL1 to DLA, and a corresponding reference voltage line RL. For example, the pixel circuit PC may be electrically connected to the driving voltage line PL through a power connection line PCL and may be electrically connected to the reference voltage line RL through a reference power connection line RCL.

The pixel circuit PC may be configured to supply a data current, corresponding to a data voltage supplied through each of corresponding data lines DL1 to DLA, to a corresponding plurality of or first and second pixel electrodes PE1 and PE2 in response to the gate signal supplied to a corresponding gate line GL. Accordingly, the plurality of or first and second emission parts EP1 and EP2 may emit light or simultaneously emit light with a data current supplied to the plurality of or first and second emission parts EP1 and EP2.

Each of the plurality of gate lines GL may be connected to the pixel circuit PC configured in each of the plurality of or first to fourth subpixels SP1 to SP4 in common. The plurality of data lines DL1 to DLA may be respectively disposed in the plurality of or first to fourth subpixels SP1 to SP4 and may be connected to a corresponding pixel circuit PC. For example, each of the plurality of or first to fourth subpixels SP1 to SP4 may include one pixel circuit PC, one gate line GL, and one data line DL.

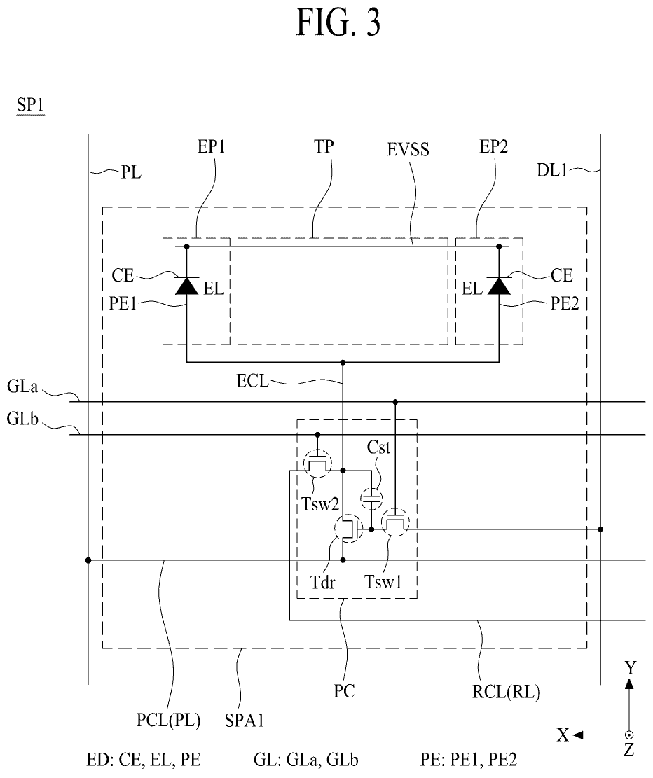

FIG. 3 is an equivalent circuit view illustrating a first subpixel illustrated in FIG. 2.

As shown in FIGS. 2 and 3, a first subpixel SP1 according to an embodiment of the present disclosure may include a light emitting device ED and a pixel circuit PC.

The light emitting device ED may be disposed (or configured) at each of the plurality of or first and second emission parts EP1 and EP2. The light emitting device ED may be disposed (or configured) in each of the plurality of or first and second emission parts EP1 and EP2 except the light-transmissive part TP in each of the plurality of subpixels SP1 to SP4. For example, the light emitting device ED may not be disposed (or configured) at the light-transmissive part TP in each of the plurality of subpixels SP1 to SP4.

The light emitting device ED of each of the plurality of or first and second emission parts EP1 and EP2 may include a pixel electrode PE (or an anode electrode), an emission layer EL over the pixel electrode PE, and a common electrode (or a cathode electrode) CE over the emission layer EL. For example, the light emitting device ED of the first emission part EP1 may include a first pixel electrode PE1, the emission layer EL over the first pixel electrode PE1, and the common electrode CE over the emission layer EL. The light emitting device ED of the second emission part EP2 may include a second pixel electrode PE2, the emission layer EL over the second pixel electrode PE2, and the common electrode CE over the emission layer EL.

According to an embodiment of the present disclosure, the emission layer EL of the light emitting device ED may be a common layer which is disposed (or configured) at the plurality of or first and second emission parts EP1 and EP2 in common. Accordingly, a light emitting device ED configured at the first subpixel SP1 (or each of the plurality of subpixels SP1 to SP4) may include the plurality of or first and second pixel electrodes PE1 and PE2, an emission layer EL over the plurality of or first and second pixel electrodes PE1 and PE2, and a common electrode CE over the emission layer EL.

According to another embodiment of the present disclosure, the emission layer EL of the light emitting device ED may be an organic emission layer, a quantum dot emission layer, or an inorganic emission layer. For example, the emission layer EL may include a hole function layer, an organic emission layer disposed on the hole function layer, and an electron function layer disposed on the organic emission layer. For example, the emission layer EL of the light emitting device ED may be changed to an inorganic light emitting diode or a micro light emitting diode.

The pixel circuit PC according to another embodiment of the present disclosure may include a first switching transistor Tsw1, a second switching transistor Tsw2, a driving transistor Tdr, and a storage capacitor Cst.

Each of the transistors Tsw1, Tsw2 and Tdr of the pixel circuit PC may be comprised of a thin-film transistor (TFT), and at least one of the thin-film transistors Tsw1, Tsw2 and Tdr may be a-Si TFT, a poly-Si TFT, an Oxide TFT, or an Organic TFT. For example, in the pixel circuit PC, some of the first switching transistor Tsw1, the second switching transistor Tsw2 and the driving transistor Tdr may be a thin-film transistor that includes a semiconductor layer (or active layer) made of low-temperature poly-Si (LTPS) having an excellent response characteristic, and the other of the first switching transistor Tsw1, the second switching transistor Tsw2 and the driving transistor Tdr may be a thin-film transistor that includes a semiconductor layer (or active layer) made of oxide having an excellent off current characteristic.

The first switching transistor Tsw1 may include a gate electrode (or control electrode) that is connected to the first gate line GLa, a first electrode that is connected to the data line DL adjacent thereto, and a second electrode that is connected to the gate electrode of the driving transistor Tdr. The gate electrode of the first switching transistor Tsw1 may be a protrusion area protruded from one side of the first gate line GLa. The first switching transistor Tsw1 may be turned on in accordance with a first gate signal supplied to the first gate line GLa and supply the data voltage supplied from the adjacent data line DL to the gate electrode of the driving transistor Tdr. For example, in the first switching transistor Tsw1, the first electrode may be a source electrode and the second electrode may be a drain electrode, but is not limited thereto, the first electrode may be a drain electrode and the second electrode may be a source electrode.

The second switching transistor Tsw2 may include a gate electrode (or control electrode) that is connected to the second gate line GLb, a first electrode that is connected to the source electrode of the driving transistor Tdr, and a second electrode that is connected to the reference voltage line RL adjacent thereto. The second switching transistor Tsw2 may supply the reference voltage supplied from the reference voltage line RL to the source electrode of the driving transistor Tdr in accordance with a second gate signal supplied to the second gate line GLb in the display mode. In addition, the second transistor Tsw2 may be turned on in accordance with a second gate signal supplied to the second gate line GLb in the sensing mode and supply a current output from the driving transistor Tdr to the adjacent reference voltage line RL or connect the source electrode of the driving transistor Tdr to the adjacent reference voltage line RL. For example, in the second switching transistor Tsw2, the first electrode may be a source electrode and the second electrode may be a drain electrode, but is not limited thereto, the first electrode may be a drain electrode and the second electrode may be a source electrode.

The storage capacitor Cst may be formed between the gate electrode and the source electrode of the driving transistor Tdr. The storage capacitor Cst may include a first capacitor electrode provided with the gate electrode GE of the driving transistor Tdr, a second capacitor electrode made of the source electrode of the driving transistor Tdr, and a dielectric layer formed at an overlap area between the first capacitor electrode and the second capacitor electrode. The storage capacitor Cst may charge (or store) a differential voltage between the gate electrode and the source electrode of the driving transistor Tdr and turns on the driving transistor Tdr in accordance with the charged voltage.

The driving transistor Tdr may include the gate electrode that is connected to the second electrode of the first switching transistor Tsw1, the source electrode that is connected to the first electrode of the second switching transistor Tsw2, and the drain electrode that is connected to the driving voltage line PL through the power connection line PCL. The source electrode of the driving transistor Tdr may be electrically connected to the first and second pixel electrodes PE1 and PE2 through the electrode connection line ECL. Accordingly, the driving transistor Tdr is turned on in accordance with the voltage of the storage capacitor Cst and controls the amount of a current flowing from the driving voltage line PL to the light emitting device ED.

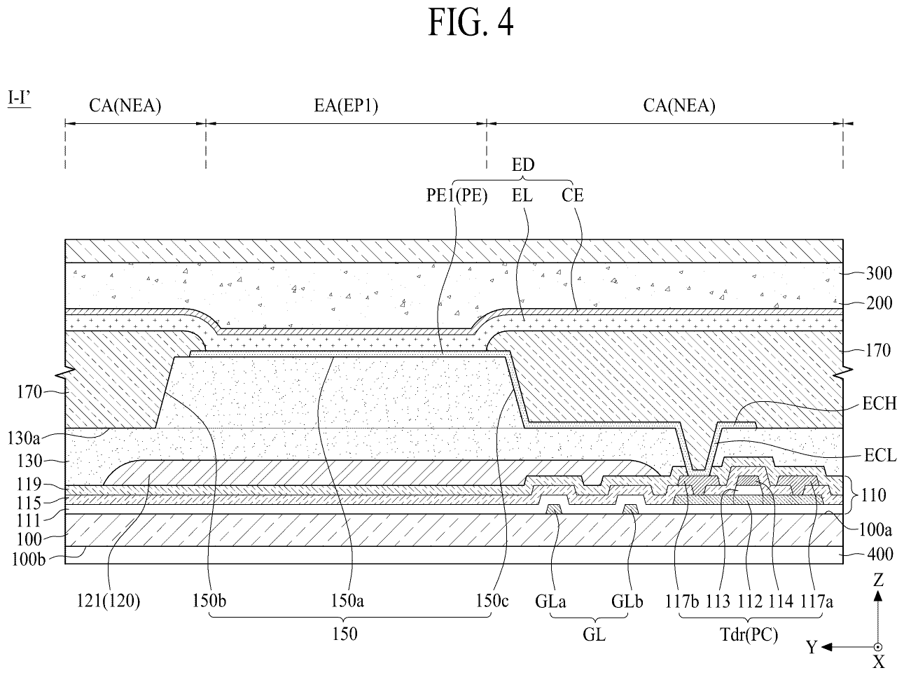

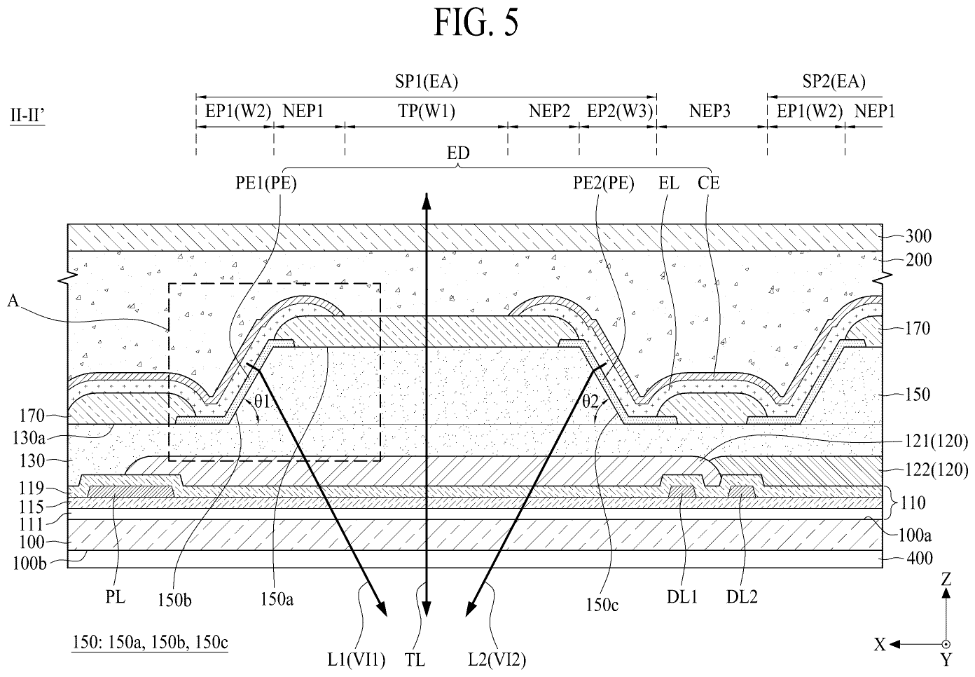

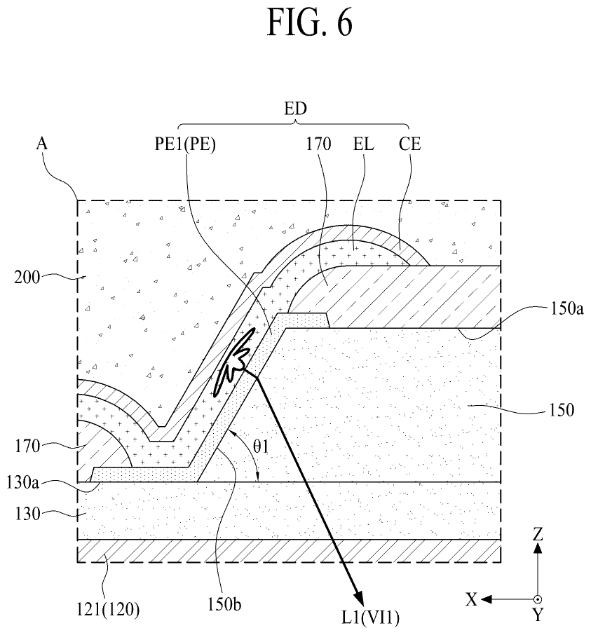

FIG. 4 is an example cross-sectional view taken along line I-I′ illustrated in FIG. 2, FIG. 5 is an example cross-sectional view taken along line II-II′ illustrated in FIG. 2, and FIG. 6 is an enlarged view of part “A” illustrated in FIG. 5.

As shown in FIGS. 2, 4, and 5, the light emitting display apparatus (or light emitting display panel) according to an embodiment of the present disclosure may include a pixel circuit layer 110, a protection layer 130, a pattern part 150, and a light emitting device ED which are disposed over the substrate 100.

The pixel circuit layer 110 may include a buffer layer 111, a pixel circuit PC, and a passivation layer 119.

The buffer layer 111 may be disposed at an entire first surface 100a of the substrate 100. The buffer layer 111 may prevent or at least reduce materials contained in the substrate 100 from spreading to a transistor layer during a high-temperature process in the manufacturing of the thin film transistor, or may prevent external water or moisture from permeating into the light emitting device ED. For example, the buffer layer 111 may be made of an inorganic insulating material.

The pixel circuit PC may include a driving thin film transistor Tdr disposed in a circuit area CA of each subpixel SP1 to SP4 (or each subpixel areas SPA1 to SPA4). The driving thin film transistor Tdr may include an active layer 112, a gate insulating layer 113, a gate electrode 114, an interlayer insulating layer 115, a drain electrode 117a, and a source electrode 117b.

The active layer 112 may be configured with a semiconductor material based on any one of amorphous silicon, polycrystalline silicon, oxide, and organic materials. The active layer 112 may include a channel region, a drain region, and a source region.

The gate insulating layer 113 may be formed over the channel region of the active layer 112. In an embodiment, the gate insulating layer 113 may be formed having an island shape over the channel region of the active layer 112, or may be formed (or configured) over an entire front surface of the buffer layer 111 or the substrate 100 including the active layer 112. For example, the gate insulating layer 113 may be made of an inorganic insulating material.

The gate electrode 114 may be formed (or configured) over a gate insulating layer 113 to overlap the channel region of an active layer 112.

The interlayer insulating layer 115 may be formed (or configured) over the gate electrode 114, and the drain region and the source region of the active layer 112. The interlayer insulating layer 115 may be formed (or configured) to cover the gate electrode 114, and the drain region and the source region of the active layer 112. For example, the interlayer insulating layer 115 may be formed (or configured) at an entire front surface of the buffer layer 111 or the substrate 100. For example, the interlayer insulating layer 115 may be made of an inorganic insulating material.

The drain electrode 117a may be formed (or configured) over the interlayer insulating layer 115 to be electrically connected to the drain region of the active layer 112. The source electrode 117b may be formed (or configured) over the interlayer insulating layer 115 to be electrically connected to the source region of the active layer 112.

The pixel circuit PC may further include the first switching thin film transistor, the second switching thin film transistor, and the storage capacitor Cst described with reference to FIG. 3. The first switching thin film transistor, the second switching thin film transistor, and the storage capacitor Cst may be formed (or configured) at the circuit area CA together with the driving thin film transistor Tdr.

The passivation layer 119 may be formed (or configured) over the substrate 100 to cover the pixel circuit PC. For example, the passivation layer 119 may be formed (or configured) to cover the drain electrode 117a and the source electrode 117b of the driving thin film transistor Tdr and the interlayer insulating layer 115. For example, the passivation layer 119 may be made of an inorganic insulating material.

The protection layer 130 may be formed (or configured) over the substrate 100 to cover the pixel circuit layer 110 or the passivation layer 119. The protection layer 130 may be formed (or configured) to have a relatively large thickness, and may provide a flat surface (or a planarization surface) 130a over the pixel circuit layer 110 or the passivation layer 119. For example, the protection layer 130 may be made of an organic material such as photo acrylic, benzocyclobutene, polyimide, and fluorine resin, or the like. For example, the protection layer 130 may be an insulating layer, an organic material layer, an uppermost insulating layer, a planarization layer, or an overcoat layer.

The pattern part 150 may be formed (or configured) over the protection layer 130 at the emission area EA of each of the plurality of subpixels SP1 to SP4. The pattern part 150 may be formed (or configured) over the flat surface 130a of the protection layer 130 at the emission area EA of each of the plurality of subpixels SP1 to SP4. For example, the pattern part 150 be formed (or configured) over the flat surface 130a of the protection layer 130 at the emission area EA to have a flat surface and a slope surface. The pattern part 150 may protrude from the flat surface 130a of the protection layer 130 at the emission area EA of each of the plurality of subpixels SP1 to SP4. For example, the pattern part 150 may protrude from the flat surface 130a of the protection layer 130 at the emission area EA to have the flat surface and the slope surface. For example, the pattern part 150 may include a cross-sectional structure having a trapezoid shape. For example, the pattern part 150 may protrude from the flat surface 130a of the protection layer 130 at the emission area EA of each of the plurality of subpixels SP1 to SP4 to include a cross-sectional structure having a trapezoid shape. For example, the pattern part 150 may be formed (or configured) of a same material as the protection layer 130, but is not limited thereto. For example, the pattern part 150 may be a protrusion part or a protrusion pattern part.

The pattern part 150 according to an embodiment of the present disclosure may include a first surface 150a, a second surface 150b, and a third surface 150c.

The first surface 150a may be a top surface, an upper surface, an uppermost surface, or a light-transmissive surface of the pattern part 150. For example, the first surface 150a may be a flat surface or a flat surface parallel to a first surface 100a of the substrate 100. The first surface 150a may be disposed (or configured) at a center region of the emission area EA.

The second surface 150b may be disposed (or configured) at a first side of the first surface 150a. The second surface 150b may have a cross-sectional structure which differs from the first surface 150a. The second surface 150b may be a slope surface which is sloped or inclined from the first side of the first surface 150a. For example, an angle (or an interior angle) between the second surface 150b and the first surface 150a may be an obtuse angle. For example, an angle (or an interior angle) between the second surface 150b and the upper surface (or flat surface) 130a of the protection layer 130 may be an acute angle. The second surface 150b may be inclined or sloped with respect to the first surface 100a of the substrate 100. The second surface 150b may be disposed (or configured) at one side region or a first edge region of the emission area EA. For example, the second surface 150b may be one side surface, one side slope surface, one side inclined surface, a first slope surface, or a first inclined surface of the pattern part 150.

The third surface 150c may be disposed (or configured) at a second side, which is different from or opposite to the first side, of the first surface 150a. The third surface 150c may have a cross-sectional structure which differs from the first surface 150a. The third surface 150c may be a slope surface which is sloped or inclined from the second side of the first surface 150a. For example, an angle (or an interior angle) between the third surface 150c and the first surface 150a may be an obtuse angle. For example, an angle (or an interior angle) between the third surface 150c and the upper surface (or flat surface) 130a of the protection layer 130 may be an acute angle. The third surface 150c may be inclined or sloped with respect to the first surface 100a of the substrate 100. The third surface 150c may be disposed (or configured) at the other side region or a second edge region of the emission area EA. For example, the second surface 150b and the third surface 150c may have a symmetric structure with respect to the first surface 150a. For example, the third surface 150c may be the other side surface, the other side slope surface, the other side inclined surface, a second slope surface, or a second inclined surface of the pattern part 150.

According to an embodiment of the present disclosure, the emission area EA of each of the plurality of subpixels SP1 to SP4 may include first to third regions by the pattern part 150. For example, the emission area EA may include a first region corresponding to (or overlapping) the first surface 150a of the pattern part 150, a second region corresponding to (or overlapping) the second surface 150b of the pattern part 150, and a third region corresponding to (or overlapping) the third surface 150c of the pattern part 150. For example, in the emission area EA, the first region may be a main region, a center region, a middle region, a transmissive area, or a light-transmissive area, the second region may be a first sub region, one side region, or a first edge region, and the third region may be a second sub region, the other side region, or a second edge region.

The light emitting device ED may be formed (or configured) over the pattern part 150. The light emitting device ED may be formed (or configured) over the pattern part 150 and the protection layer 130. For example, the light emitting device ED may be configured to emit light toward the substrate 100 according to a bottom emission type, but embodiments according to the present disclosure are not limited thereto. For example, the light emitting device ED may be a light emitting device layer or a common emission layer (or a common light emitting layer).

The light emitting device ED according to an embodiment of the present disclosure may include a pixel electrode PE, an emission layer EL, and a common electrode CE. For example, the pixel electrode PE may be a first electrode, an anode electrode, or a transparent pixel electrode. The common electrode CE may be a second electrode, a cathode electrode, a counter electrode (or opposite electrode), or reflective electrode.

The pixel electrode PE may be formed (or configured) over the pattern part 150. The pixel electrode PE may be formed (or configured) over the pattern part 150 and may be formed (or configured) over a portion of the protection layer 130 adjacent to the pattern part 150. The pixel electrode PE may be electrically connected to a source electrode 117b (or a drain electrode 117a) of the driving thin film transistor Tdr. One end of the pixel electrode PE adjacent to the circuit area CA may be electrically connected to the source electrode 117b of the driving thin film transistor Tdr through an electrode contact hole ECH provided at the protection layer 130 and the passivation layer 119.

According to an embodiment of the present disclosure, the pixel electrode PE at the emission area EA of each of the plurality of subpixels SP1 to SP4 may include first and second pixel electrodes PE1 and PE2.

The first pixel electrode PE1 may be formed (or configured) over the second surface (or the first slope surface) 150b of the pattern part 150. The first pixel electrode PE1 may have a size greater than that of the second surface 150b of the pattern part 150. For example, a first edge portion of the first pixel electrode PE1 adjacent to the first surface of the pattern part 150 may contact one edge portion of the first surface 150a of the pattern part 150. For example, a second edge portion, which is opposite to the first edge portion, of the first pixel electrode PE1 may contact a portion of the protection layer 130 adjacent to the pattern part 150. A center portion between the first edge portion and the second edge portion of the first pixel electrode PE1 may contact the second surface 150b of the pattern part 150 and may be inclined or sloped to correspond to the second surface 150b of the pattern part 150.

The second pixel electrode PE2 may be formed (or configured) over the third surface (or the second slope surface) 150c of the pattern part 150. The second pixel electrode PE2 may have a size greater than that of the third surface 150c of the pattern part 150. For example, a first edge portion of the second pixel electrode PE2 adjacent to the first surface of the pattern part 150 may contact the other edge portion of the first surface 150a of the pattern part 150. For example, a second edge portion, which is opposite to the first edge portion, of the second pixel electrode PE2 may contact a portion of the protection layer 130 adjacent to the pattern part 150. A center portion between the first edge portion and the second edge portion of the second pixel electrode PE2 may contact the third surface 150c of the pattern part 150 and may be inclined or sloped to correspond to the third surface 150c of the pattern part 150.

According to an embodiment of the present disclosure, each of the first and second pixel electrodes PE1 and PE2 may be spaced apart from (or electrically disconnected from) one another at the emission area EA and may be commonly connected to the pixel circuit PC at the circuit area CA. For example, the pixel circuit PC configured at each of the plurality of subpixels SP1 to SP4 may include a thin film transistor (TFT) Tdr which is commonly connected to the first and second pixel electrodes PE1 and PE2.

According to an embodiment of the present disclosure, one end of each of the first and second pixel electrodes PE1 and PE2 adjacent to the circuit area CA may be electrically connected to the electrode connection line ECL. The electrode connection line ECL may be electrically connected to a source electrode 117b (or a drain electrode 117a) of the driving thin film transistor Tdr. The electrode connection line ECL may be electrically connected to the source electrode 117b of the driving thin film transistor Tdr through the electrode contact hole ECH provided at the protection layer 130 and the passivation layer 119. Accordingly, each of the first and second pixel electrodes PE1 and PE2 may be commonly connected to the source electrode 117b of the driving thin film transistor Tdr through the electrode connection line ECL.

The pixel electrode PE or the first and second pixel electrodes PE1 and PE2 and the electrode connection line ECL may be made of a transparent conductive material such as transparent conductive oxide (TCO). For example, the pixel electrode PE or the first and second pixel electrodes PE1 and PE2 and the electrode connection line ECL may include indium tin oxide (ITO) or indium zinc oxide (IZO), but is not limited thereto.

The emission layer EL may be formed (or configured) over the pixel electrode PE. The emission layer EL may be formed (or configured) over the first and second pixel electrodes PE1 and PE2 and may directly contact each of the first and second pixel electrodes PE1 and PE2. The emission layer EL may be additionally formed (or configured) over the protection layer 130 as well as the pixel electrode PE or the first and second pixel electrodes PE1 and PE2. The emission layer EL may be a common layer which is formed (or configured) at each of the plurality of subpixels SP1 to SP4 in common. For example, the emission layer EL may be formed (or configured) at the other region, except the light-transmissive part TP, of each of the plurality of subpixels SP1 to SP4. For example, the emission layer EL may not be disposed (or configured) at the light-transmissive part TP in each of the plurality of subpixels SP1 to SP4. For example, a region, corresponding to (or overlapping) the light-transmissive part TP of each of the plurality of subpixels SP1 to SP4, of a region of the emission layer EL may be removed. For example, the emission layer EL may include an opening portion (or an open region or a removal region) which corresponds to (or overlaps) the light-transmissive part TP of each of the plurality of subpixels SP1 to SP4.

The emission layer EL according to an embodiment of the present disclosure may include two or more organic emission layers configured to emit white light. For example, the emission layer EL may include a stack structure that two or more organic emission layers are stacked. For example, the emission layer EL may include a stack structure that a first organic emission layer and a second organic emission layer are stacked. As an embodiment, the emission layer EL may include a first organic emission layer and a second organic emission layer to emit white light by mixing a first light and a second light. For example, the first organic emission layer may include any one of a blue organic emission layer, a green organic emission layer, a red organic emission layer, a yellow organic emission layer, and a yellow-green organic emission layer to emit the first light. For example, the second organic emission layer may include an organic emission layer capable of emitting the second light to obtain white light in the emission layer EL by mixing the first light of a blue organic emission layer, a green organic emission layer, a red organic emission layer, a yellow organic emission layer, or a yellow-green organic emission layer. The emission layer EL according to another embodiment may include any one of a blue organic emission layer, a green organic emission layer, and a red organic emission layer. Additionally, the emission layer EL may include a charge generating layer interposed between the first organic emission layer and the second organic emission layer.

According to another embodiment of the present disclosure, each of the plurality of subpixels SP1 to SP4 may include an emission layer EL formed (or configured) to emit light of different colors. For example, an emission layer EL of the first subpixel SP1 may include a red organic emission layer. An emission layer EL of the second subpixel SP2 may include a blue organic emission layer. An emission layer EL of the third subpixel SP3 may include two or more organic emission layer for emitting white light. An emission layer EL of the fourth subpixel SP4 may include a green organic emission layer.

According to another embodiment of the present disclosure, when each of the plurality of pixels P includes a red subpixel SP1, a blue subpixel SP2, and a green subpixel SP4, the emission layer EL of the red subpixel SP1 may include a red organic emission layer, the emission layer of the blue subpixel SP2 may include a blue organic emission layer, and the emission layer EL of the green subpixel SP4 may include a green organic emission layer.

The common electrode CE may be formed (or configured) over the emission layer EL. The common electrode CE may be formed (or configured) over the emission layer EL and may directly contact the emission layer EL. The common electrode CE may be formed (or configured) at the other region, except the light-transmissive part TP, of each of the plurality of subpixels SP1 to SP4. For example, the common electrode CE may not be disposed (or configured) at the light-transmissive part TP in each of the plurality of subpixels SP1 to SP4. For example, a region, corresponding to (or overlapping) the light-transmissive part TP of each of the plurality of subpixels SP1 to SP4, of a region of the common electrode CE may be removed. For example, the common electrode CE may include an opening portion (or an open region or a removal region) which corresponds to (or overlaps) the light-transmissive part TP of each of the plurality of subpixels SP1 to SP4.

The common electrode CE according to an embodiment of the present disclosure may include a metal material having a high reflectance to reflect the incident light emitted from the emission layer EL toward the substrate 100. The common electrode CE may include an opaque conductive material having high reflectivity. For example, the common electrode CE may include a single-layered structure or multi-layered structure of any one material selected of aluminum (Al), argentums (Ag), molybdenum (Mo), titanium (Ti), or copper (Cu), or alloy of two or more materials selected from aluminum (Al), argentums (Ag), molybdenum (Mo), titanium Ti, or copper (Cu). For example, the common electrode CE may be formed in a three-layer structure of IZO/MoTi/ITO or ITO/MoTi/ITO, or may be formed in a four-layer structure of ITO/Cu/MoTi/ITO, but embodiments of the present disclosure are not limited thereto.

The light emitting device ED may generate light responsive to current supplied from the pixel circuit PC and thus, may emit light. According to an embodiment of the present disclosure, the pixel electrode PE, the emission layer EL, and the common electrode CE which are formed over the pattern part 150 may configure (or implement) the first emission part EP1 and the second emission part EP2.

The first emission part EP1 may include the first pixel electrode PE1, the emission layer EL, and the common electrode CE which are formed (or configured) over the second surface (or first slope surface) 150b of the pattern part 150. The first emission part EP1 may emit light by light emission of the emission layer EL in accordance with a current applied from the pixel circuit PC to the first pixel electrode PE1.

The second emission part EP2 may include the second pixel electrode PE2, the emission layer EL, and the common electrode CE which are formed (or configured) over the third surface (or second slope surface) 150c of the pattern part 150. The second emission part EP2 may emit light by light emission of the emission layer EL in accordance with a current applied from the pixel circuit PC to the second pixel electrode PE2.

The emission layer EL at each of the first and second emission parts EP1 and EP2 may simultaneously emit light with a current commonly supplied to the first and second pixel electrodes PE1 and PE2 through the electrode connection line ECL from the driving thin film transistor Tdr of the pixel circuit PC.

According to an embodiment of the present disclosure, the light-transmissive part TP may be disposed (or configured) at the first surface 150a of the pattern part 150 having the flat structure (or the planar structure), and thus, light (or a first light or transmitted light) TL passing through (or transmission) the light-transmissive part TP may be output in a direction perpendicular to the first surface 100a of the substrate 100. Accordingly, a user (or a viewer) may see a thing or a background, disposed at a rear surface or a front surface of the light emitting display apparatus, through the light-transmissive part TP of each of the plurality of subpixels SP.

According to an embodiment of the present disclosure, the first emission part EP1 may include the emission layer EL which is disposed (or configured) over the first pixel electrode PE1 having the slope structure, and thus, light (or a second light or a first viewing angle light) L1 emitted from the emission layer EL of the first emission part EP1 may be output in a direction which is inclined with respect to the first surface 100a of the substrate 100. For example, the light L1 emitted from the first emission part EP1 may be output by the second surface 150b of the pattern part 150 in a direction which is inclined with respect to the first surface 100a of the substrate 100. In addition, the light L1 emitted from the first emission part EP1 may be output in an inclined direction with respect to the first surface 100a of the substrate 100 due to a refractive index difference at the first slope surface 150b of the pattern part 150. Accordingly, a light output angle of the light L1 emitted from the first emission part EP1 may differ from an angle of the light TL passing through the light-transmissive part TP.

According to an embodiment of the present disclosure, as illustrated in FIG. 6, a first angle (or interior angle) 01 between the upper surface (or flat surface) 130a of the protection layer 130 and the second surface 150b of the pattern part 150 may be an acute angle. For example, a light extraction efficiency of the light L1 emitted from the first emission part EP1 may be determined based on the first angle θ1. For example, with respect to the light output surface (or light extraction surface) 100b of the substrate 100, the light extraction efficiency of the light L1 emitted from the first emission part EP1 may be affected by an angle of light emitted from the first emission part EP1, an angle of light emitted from the first emission part EP1 to the pattern part 150, and an angle of light emitted from the light output surface 100b of the substrate 100 to the outside. For example, the first angle θ1 may be set so that an angle of the light L1, which is emitted from the first emission part EP1 and is output to the outside of the light output surface 100b of the substrate 100, is greater than 30 degrees and smaller than 45 degrees, and thus, the light extraction efficiency of the light L1 emitted from the first emission part EP1 may increase or be maximized.

According to an embodiment of the present disclosure, the first angle θ1 may be equal to each other at each of the plurality of subpixels SP1 to SP4, but embodiments of the present disclosure are not limited thereto. For example, the first angle θ1 may differ at one or more of the plurality of subpixels SP1 to SP4. For example, the first angle θ1 may differ at each of the red subpixel, the blue subpixel, the white subpixel, and the green subpixel. That is, the first angle θ1 may differ for each subpixel.

According to an embodiment of the present disclosure, the second emission part EP2 may include the emission layer EL which is disposed (or configured) over the second pixel electrode PE2 having the slope structure, and thus, light (or a third light or a second viewing angle light) L2 emitted from the emission layer EL of the second emission part EP2 may be output in a direction which is inclined with respect to the first surface 100a of the substrate 100. For example, the light L2 emitted from the second emission part EP2 may be output by the third surface 150c of the pattern part 150 in a direction which is inclined with respect to the first surface 100a of the substrate 100. In addition, the light L2 emitted from the second emission part EP2 may be output in an inclined direction with respect to the first surface 100a of the substrate 100 due to a refractive index difference at the second slope surface 150c of the pattern part 150. Accordingly, a light output angle of the light L2 emitted from the second emission part EP2 may differ from an angle of the light TL passing through the light-transmissive part TP.

According to an embodiment of the present disclosure, a second angle (or interior angle) 02 between the upper surface (or flat surface) 130a of the protection layer 130 and the third surface 150c of the pattern part 150 may be an acute angle. For example, the second angle θ2 may be equal to or different from the first angle θ1 described above with reference to FIG. 6. For example, like the first angle θ1 described above with reference to FIG. 6, the second angle θ2 may be set so that an angle of the light L2, which is emitted from the second emission part EP2 and is output to the outside of the light output surface 100b of the substrate 100, is greater than 30 degrees and smaller than 45 degrees, and thus, the light extraction efficiency of the light L2 emitted from the second emission part EP2 may increase or be maximized.

The light emitting display apparatus (or the light emitting display panel) according to an embodiment of the present disclosure may further include a bank layer 170.

The bank layer 170 may be formed (or configured) to cover all of the light-transmissive part TP or an edge portion of each of the plurality of or first and second emission parts EP1 and EP2 at each of the plurality of subpixels SP. The bank layer 170 may be formed of an organic material such as benzocyclobutene (BCB)-based resin, acrylic-based resin, polyimide resin, or the like. For example, the bank layer 170 may be formed of a transparent material and may be a transparent bank.

According to an embodiment of the present disclosure, the bank layer 170, as illustrated in FIG. 5, may be formed (or configured) to cover all of the light-transmissive part TP of each of the plurality of subpixels SP. For example, in each of the plurality of subpixels SP, the bank layer 170 may be formed over the first surface 150a of the pattern part 150 and may be configured to cover all of the first surface 150a of the pattern part 150. The bank layer 170 configured over the first surface 150a of the pattern part 150 may provide a flat surface over the first surface 150a of the pattern part 150, and thus, changing of a light path passing through the light-transmissive part TP may be minimized.

According to an embodiment of the present disclosure, the bank layer 170, as illustrated in FIGS. 4 and 5, may be formed (or configured) to cover an edge portion of each of the pixel electrode PE at each of the plurality of subpixels SP. In each of the plurality of subpixels SP, the bank layer 170 may be formed (or configured) to cover an edge portion of each of the first and second pixel electrodes PE1 and PE2. For example, the bank layer 170 configured over the first surface 150a of the pattern part 150 may be formed (or configured) to cover the edge portion of each of the first and second pixel electrodes PE1 and PE2 adjacent to the light-transmissive part TP. In addition, the bank layer 170 may be formed over the protection layer 130 between adjacent subpixels SP1 to SP4.

According to an embodiment of the present disclosure, the light-transmissive part TP may correspond to the other portion, except an edge portion, of the first surface 150a of the pattern part 150 covered by the bank layer 170 and may have a first width W1 along the first direction X. The first emission part EP1 may correspond to the other portion, except an edge portion, of the first pixel electrode PE1 covered by the bank layer 170 and may have a second width W2 along the first direction X. The second emission part EP2 may correspond to the other portion, except an edge portion, of the second pixel electrode PE2 covered by the bank layer 170 and may have a third width W3 along the first direction X. For example, the first width W1 of the light-transmissive part TP may be greater than that of the second width W2 of the first emission part EP1 and the third width W3 of the second emission part EP2. The second width W2 of the first emission part EP1 and the third width W3 of the second emission part EP2 may be equal to each other. The first width W1 of the light-transmissive part TP may be equal to a sum of the second width W2 of the first emission part EP1 and the third width W3 of the second emission part EP2, but is not limited thereto. For example, the first width W1 of the light-transmissive part TP may be greater or smaller than that of the sum of the second width W2 of the first emission part EP1 and the third width W3 of the second emission part EP2.

The light emitting display apparatus (or the light emitting display panel) according to an embodiment of the present disclosure may further include a non-emission part NEP corresponding to the bank layer 170. For example, the emission area EA of each of the plurality of pixels P may further include a first non-emission part NEP1 corresponding to the bank layer 170 between the light-transmissive part TP and the first emission part EP1, a second non-emission part NEP2 corresponding to the bank layer 170 between the light-transmissive part TP and the second emission part EP2, and a third non-emission part NEP3 corresponding to the bank layer 170 between the adjacent subpixels SP1 to SP4.

According to an embodiment of the present disclosure, the emission layer EL of the light emitting device ED may be formed (or configured) over the pixel electrode PE and the bank layer 170. For example, the bank layer 170 may be formed between the emission layer EL and the pixel electrode PE or between the emission layer EL and the protective layer 130.

The light emitting display apparatus (or the light emitting display panel) according to an embodiment of the present disclosure may further include a color filter layer 120.

The color filter layer 120 may be disposed between the substrate 100 and the protection layer 130 to overlap with at least one emission area EA. The color filter layer 120 according to an embodiment of the present disclosure may be disposed between the passivation layer 119 and the protection layer 130 to overlap with the emission area EA. The color filter layer 120 according to another embodiment of the present disclosure may be disposed between the interlayer insulating layer 115 and the passivation layer 119 or between the substrate 100 and the interlayer insulating layer 115 to overlap with the emission area EA.

The color filter layer 120 may have a larger size than that of the emission area EA. For example, when the color filter layer 120 has a greater size than that of the emission area EA, light leakage through which internal light travels toward the adjacent subpixels SP1 to SP4 may be reduced or minimized.

The color filter layer 120 according to an embodiment of the present disclosure may include a color filter which transmits only the wavelength of a color set in each subpixel SP1 to SP4 of the light emitted (or extracted) from the light emitting device ED toward the substrate 100. For example, the color filter layer 120 may transmit the red wavelength, green wavelength, or blue wavelength. For example, the color filter layer 120 provided at the first subpixel SP1 may include a red color filter 121, the color filter layer 120 provided at the second subpixel SP2 may include a blue color filter 122, and the color filter layer 120 provided at the fourth subpixel SP4 may include a green color filter 123. The third subpixel SP3 may not include a color filter layer 120 or may include a transparent material to compensate a step difference between adjacent pixels, thereby emitting white light.

According to another embodiment of the present disclosure, when each of the plurality of pixels P includes a red subpixel SP1, a blue subpixel SP2, and a green subpixel SP4, the color filter layer 120 may be omitted.

The light emitting display apparatus (or the light emitting display panel) according to an embodiment of the present disclosure may further include an encapsulation part 200.

The encapsulation part 200 may be formed over the substrate 100 to cover the light emitting device ED. The encapsulation part 200 may be formed over the common electrode CE of the light emitting device ED. For example, the encapsulation part 200 may surround the display area. The encapsulation part 200 may protect the thin film transistor and the emission layer EL or the like from external impact and prevent oxygen or/and water (or moisture) and particles from being permeated into the emission layer EL.

The encapsulation part 200 according to an embodiment of the present disclosure may include a plurality of inorganic encapsulation layer. In addition, the encapsulation part 200 may further include at least one organic encapsulation layer interposed between the plurality of inorganic encapsulation layer. The organic encapsulation layer may be expressed as a particle overlay layer.

The light emitting display apparatus (or the light emitting display panel) according to an embodiment of the present disclosure may further include a counter substrate 300. The counter substrate 300 may be configured to be coupled to the encapsulation part 200. The counter substrate 300 may be made of a transparent glass material or a transparent plastic material.

According to another embodiment of the present disclosure, the encapsulation part 200 may be changed to a filler that entirely surrounds (or completely surrounds) the display area DA, in this case, the counter substrate 300 may be bonded to the substrate 100 using the filler. The filler may include a getter material that absorbs oxygen or/and water (or moisture). For example, when the encapsulation part 200 includes a plurality of inorganic encapsulation layers, the counter substrate 300 may be omitted.

The light emitting display apparatus (or the light emitting display panel) according to an embodiment of the present disclosure may further include a polarization member 400.

The polarization member 400 may be configured to block external light reflected by the pixel circuit PC or the like. For example, the polarization member 400 may be configured as a circular polarization member or a circular polarization film. The polarization member 400 may be disposed at or coupled to the light output surface (or a second surface or a rear surface) 100b of the substrate 100 using a coupling member (or a transparent adhesive member).

As described above, in the light emitting display apparatus according to an embodiment of the present disclosure, external light may pass through (or transmit) the light-transmissive part TP of each of the plurality of subpixels SP, and thus, may provide, through the light-transmissive part TP, a user (or a viewer) with a thing or a background disposed at the rear surface or the front surface of the light emitting display apparatus. For example, a user (or a viewer) may see a thing or a background, disposed at the rear surface or the front surface of the light emitting display apparatus, through the light-transmissive part TP of each of the plurality of subpixels SP and may see an image, based on lights L1 and L2 respectively emitted from the first and second emission parts EP1 and EP2 of each of the plurality of subpixels SP. Accordingly, the light emitting display apparatus according to an embodiment of the present disclosure may implement a transparent display apparatus.

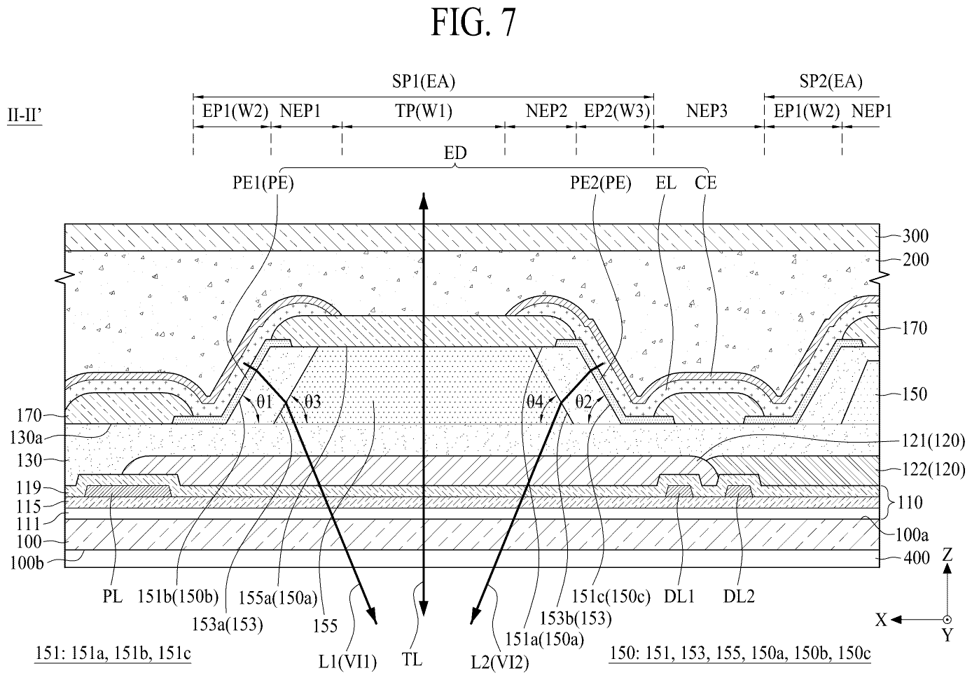

FIG. 7 is another example cross-sectional view taken along line II-II′ illustrated in FIG. 2. FIG. 7 illustrates an embodiment implemented by modifying the pattern part at the light emitting display apparatus (or the light emitting display panel) described above with reference to FIGS. 2 to 6. Therefore, in the following descriptions of FIG. 7, the other elements except the pattern part and relevant elements are referred to by like reference numerals, and their repetitive descriptions are omitted. Descriptions of the light emitting display apparatus (or the light emitting display panel) illustrated in FIGS. 2 to 6 may be included in the descriptions of the light emitting display apparatus (or the light emitting display panel) illustrated in FIG. 7.

As shown in FIGS. 2 and 7, in the light emitting display apparatus (or the light emitting display panel) according to another embodiment of the present disclosure, the pattern part 150 may include a first pattern layer 151, a groove portion 153, and a second pattern layer 155.

The pattern part 150 may be formed (or configured) over the protection layer 130. The pattern part 150 may be formed (or configured) over the flat surface 130a of the protection layer 130 at the emission area EA to have a flat surface 150a and a slope surface 150b and 150c. For example, the pattern part 150 may protrude from the flat surface 130a of the protection layer 130 to have a flat surface 150a and a slope surface 150b and 150c. For example, the pattern part 150 may protrude from the flat surface 130a of the protection layer 130 to include a cross-sectional structure having a trapezoid shape. For example, the first pattern layer 151 may be a protrusion part or a protrusion pattern part.

The first pattern layer 151 according to an embodiment of the present disclosure may include an upper surface (or an upper side surface) 151a, a first lateral surface 151b, and a second lateral surface 151c. Each of the upper surface 151a, the first lateral surface 151b, and the second lateral surface 151c of the first pattern layer 151 may be a same or substantially a same as each of the first surface 150a, the second surface 150b, and the third surface 150c of the pattern part 150 described above with reference to FIGS. 4 to 6, respectively, and thus, their repeated descriptions are omitted. The first lateral surface 151b of the first pattern layer 151 may be a first slope surface 150b of the pattern part 150, and the second lateral surface 151c of the first pattern layer 151 may be a second slope surface 150c of the pattern part 150.

The groove portion 153 may be at the first pattern layer 151 and may be configured to overlap the light-transmissive part TP. The groove portion 153 may be formed (or configured) to be recessed (or concave) from the upper surface 151a of the first pattern layer 151. The groove portion 153 may include a first slope surface 153a and a second slope surface 153b. For example, the groove portion 153 may include a cross-sectional structure having a trapezoid shape which includes the first slope surface 153a and the second slope surface 153b.

The first slope surface (or first inclined surface) 153a may be inclined or sloped with respect to the upper surface 151a of the first pattern layer 151 (or the first surface 150a of the pattern part 150) and/or the substrate 100. The first slope surface 153a may be spaced apart from the first lateral surface 151b of the first pattern layer 151 (or the second surface 150b of the pattern part 150). The first slope surface 153a may be parallel to the first lateral surface 151b of the first pattern layer 151 (or the second surface 150b of the pattern part 150), but is not limited thereto. For example, the first slope surface 153a may overlap the bank layer 170 covering an edge portion of the first emission part EP1, but is not limited thereto. For example, the first slope surface 153a may overlap an edge portion of the light-transmissive part TP so as to be spaced apart from the first emission part EP1. For example, a portion of the first slope surface 153a may overlap the first pixel electrode PE1 of the first emission part EP1, but is not limited thereto and may not overlap the first pixel electrode PE1 of the first emission part EP1. For example, the first slope surface 153a may be one side surface, one side slope surface, one side inclined surface, a first slope surface, a first inclined surface, or a first light refraction surface of the first pattern layer 151.

According to an embodiment of the present disclosure, a third angle (or an interior angle) θ3 between the first slope surface 153a and the flat surface 130a of the protection layer 130 may be equal to or different from a first angle (or an interior angle) θ1 between the first lateral surface 151b of the first pattern layer 151 (or the second surface 150b of the pattern part 150) and the flat surface 130a of the protection layer 130. The third angle θ3 may be smaller than or equal to the first angle θ1. For example, the third angle θ3 may be smaller than or equal to the first angle θ1 within an acute-angle range. The third angle θ3 may be equal to each other at each of the plurality of subpixels SP1 to SP4, but embodiments of the present disclosure are not limited thereto. For example, the third angle θ3 may differ at one or more of the plurality of subpixels SP1 to SP4. For example, the third angle θ3 may differ at each of the red subpixel, the blue subpixel, the white subpixel, and the green subpixel. That is, the third angle θ3 may differ for each subpixel.

The second slope surface (or second inclined surface) 153b may be inclined or sloped with respect to the upper surface 151a of the first pattern layer 151 (or the first surface 150a of the pattern part 150) and/or the substrate 100. The second slope surface 153b may be spaced apart from the second lateral surface 151c of the first pattern layer 151 (or the third surface 150c of the pattern part 150). The second slope surface 153b may be parallel to the second lateral surface 151c of the first pattern layer 151 (or the third surface 150c of the pattern part 150), but is not limited thereto. For example, the second slope surface 153b may overlap the bank layer 170 covering an edge portion of the second emission part EP2, but is not limited thereto. For example, the second slope surface 153b may overlap an edge portion of the light-transmissive part TP so as to be spaced apart from the second emission part EP2. For example, a portion of the second slope surface 153b may overlap the second pixel electrode PE2 of the second emission part EP2, but is not limited thereto and may not overlap the second pixel electrode PE2 of the second emission part EP2. For example, the second slope surface 153b may be the other side surface, the other side slope surface, the other side inclined surface, a second slope surface, a second inclined surface, or a second light refraction surface of the first pattern layer 151.

According to an embodiment of the present disclosure, a fourth angle (or an interior angle) 04 between the second slope surface 153b and the flat surface 130a of the protection layer 130 may be equal to or different from a second angle (or an interior angle) 02 between the second lateral surface 151c of the first pattern layer 151 (or the third surface 150c of the pattern part 150) and the flat surface 130a of the protection layer 130. The fourth angle θ4 may be smaller than or equal to the second angle θ2. For example, the fourth angle θ4 may be smaller than or equal to the second angle θ2 within an acute-angle range. The fourth angle θ4 may be equal to each other at each of the plurality of subpixels SP1 to SP4, but embodiments of the present disclosure are not limited thereto. For example, the fourth angle θ4 may differ at one or more of the plurality of subpixels SP1 to SP4. For example, the fourth angle θ4 may differ at each of the red subpixel, the blue subpixel, the white subpixel, and the green subpixel. That is, the fourth angle θ4 may differ for each subpixel.

The second pattern layer 155 may be formed (or configured) to prevent color mixture between the light L1 emitted from the first emission part EP1 and the light L2 emitted from the second emission part EP2. In addition, the second pattern layer 155 may be formed (or configured) to block a light path between the light L1 emitted from the first emission part EP1 and the light L2 emitted from the second emission part EP2. The second pattern layer 155 may be formed (or configured) at the groove portion 153. The second pattern layer 155 may be formed (or configured) to be filled into the groove portion 153.

An upper surface (or an upper side surface) 155a of the second pattern layer 155 may be provided (or configured) as a flat surface. The upper surface 155a of the second pattern layer 155 may form (or configure) the first surface 150a of the pattern part 150. For example, the first surface (or an upper surface) 150a of the pattern part 150 may include the upper surface 151a of the first pattern layer 151 and the upper surface 155a of the second pattern layer 155. For example, the first surface (or the upper surface) 150a of the pattern part 150 may be provided (or configured) as a flat surface by the upper surface 151a of the first pattern layer 151 and the upper surface 155a of the second pattern layer 155. The upper surface 155a of the second pattern layer 155 may be covered by the bank layer 170.

The first pattern layer 151 and the second pattern layer 155 may be formed (or configured) to have different refractive indexes. The first pattern layer 151 and the second pattern layer 155 may be formed (or configured) of organic materials having different refractive indexes. For example, a refractive index of the second pattern layer 155 may be lower than that of the first pattern layer 151. For example, the second pattern layer 155 may be formed (or configured) in an organic material or a material having a refractive index which is lower than the first pattern layer 151. For example, the first pattern layer 151 may be a high refraction layer or a high refraction pattern layer. The second pattern layer 155 may be a low refraction layer or a low refraction pattern layer. For example, the first pattern layer 151 may be formed (or configured) with a same material as the protective layer 130, but is not limited thereto.

According to an embodiment of the present disclosure, the light L1 emitted from the first emission part EP1 and the light L2 emitted from the second emission part EP2 may be output in an inclined direction with respect to the first surface 100a of the substrate 100 due to a refractive index difference between the first pattern layer 151 and the second pattern layer 152 of the pattern part 150. For example, the light L1 emitted from the first emission part EP1 may be output in an inclined direction with respect to the first surface 100a of the substrate 100 due to a refractive index difference at the first slope surface 153a of the groove part 153. The light L2 emitted from the second emission part EP2 may be output in an inclined direction with respect to the first surface 100a of the substrate 100 due to a refractive index difference at the second slope surface 153b of the groove part 153.

According to an embodiment of the present disclosure, light, traveling to the second emission part EP2, of the light L1 emitted from the first emission part EP1 may be blocked by the second pattern layer 155. Light, traveling to the first emission part EP1, of the light L2 emitted from the second emission part EP2 may be blocked by the second pattern layer 155. Accordingly, color mixture between the light L1 emitted from the first emission part EP1 and the light L2 emitted from the second emission part EP2 may be prevented or minimized.

The light emitting display apparatus according to another embodiment of the present disclosure described above with reference to FIGS. 2 and 7 may provide a same effect as that of the light emitting display apparatus according to an embodiment of the present disclosure described above with reference to FIGS. 2 to 6, and color mixture between the light L1 emitted from the first emission part EP1 and the light L2 emitted from the second emission part EP2 may be prevented or minimized by the second pattern layer 155.

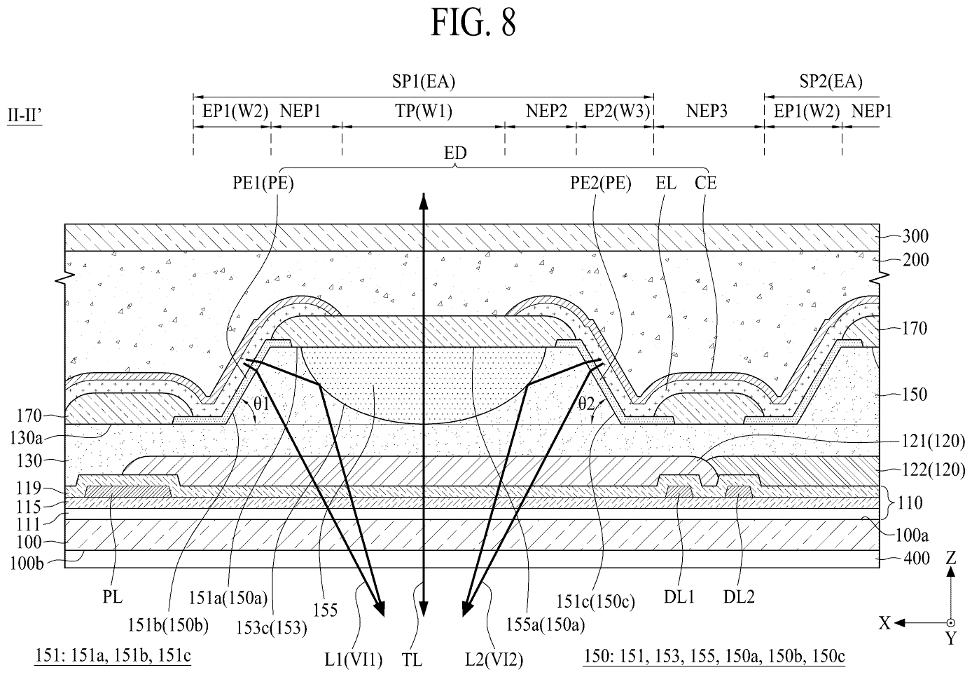

In the description of the pattern part 150 described above with reference to FIGS. 2 and 7, the groove portion 153 has been described as including a trapezoid cross-sectional structure including the first slope surface 153a and the second slope surface 153b of the groove portion 153, but embodiments of the present disclosure are not limited thereto. For example, as illustrated in FIG. 8, the groove portion 153 of the pattern part 150 may be configured to include a curved structure.

As shown in FIGS. 2 and 8, the groove portion 153 according to another embodiment of the present disclosure may be formed (or configured) to be recessed from the upper surface 151a of the first pattern layer 151 (or the first surface 150a of the pattern part 150) overlapping the light-transmissive part TP. The groove portion 153 may be formed (or configured) to be recessed (or concave) from the upper surface 151a of the first pattern layer 151 (or the first surface 150a of the pattern part 150) to include a curved surface 153c. For example, the groove portion 153 may include a cross-sectional structure including the curved surface 153c. For example, the groove portion 153 may include a semicircular cross-sectional shape, a semioval cross-sectional shape, or a parabolic cross-sectional shape. The second pattern layer 155 may be filled into the groove portion 153.

According to another embodiment of the present disclosure, the light L1 emitted from the first light emitting part EP1 may be output in a direction inclined with respect to the first surface 100a of the substrate 100 due to a difference in refractive index on the curved surface 153c of the groove part 153. The light L2 emitted from the second light emitting part EP2 may be output in a direction inclined with respect to the first surface 100a of the substrate 100 due to a difference in refractive index on the curved surface 153c of the groove part 153.

According to another embodiment of the present disclosure, light, traveling to the second emission part EP2, of the light L1 emitted from the first emission part EP1 may be blocked by the second pattern layer 155 filled in the groove part 153. Light, traveling to the first emission part EP1, of the light L2 emitted from the second emission part EP2 may be blocked by the second pattern layer 155 filled in the groove part 153. Accordingly, color mixture between the light L1 emitted from the first emission part EP1 and the light L2 emitted from the second emission part EP2 may be prevented or minimized.

The light emitting display apparatus according to another embodiment of the present disclosure described above with reference to FIGS. 2 and 8 may provide a same effect as that of the light emitting display apparatus according to an embodiment of the present disclosure described above with reference to FIGS. 2 to 6, and color mixture between the light L1 emitted from the first emission part EP1 and the light L2 emitted from the second emission part EP2 may be prevented or minimized by the second pattern layer 155.

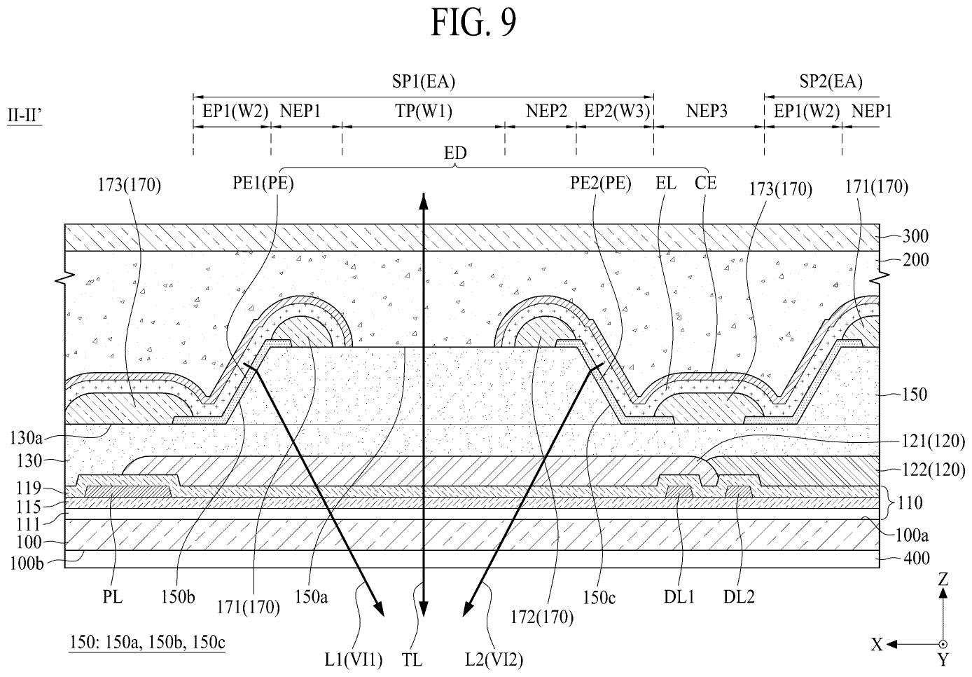

FIG. 9 is another example cross-sectional view taken along line II-II′ illustrated in FIG. 2. FIG. 9 illustrates an embodiment implemented by modifying the bank layer at the light emitting display apparatus (or the light emitting display panel) described above with reference to FIGS. 2 to 6. Therefore, in the following descriptions of FIG. 9, the other elements except the bank layer and relevant elements are referred to by like reference numerals, and their repetitive descriptions are omitted. Descriptions of the light emitting display apparatus (or the light emitting display panel) illustrated in FIGS. 2 to 6 may be included in the descriptions of the light emitting display apparatus (or the light emitting display panel) illustrated in FIG. 9.

As shown in FIGS. 2 and 9, in the light emitting display apparatus (or the light emitting display panel) according to another embodiment of the present disclosure, the bank layer 170 may be formed (or configured) to cover an edge portion of each of the plurality of or first and second emission parts EP1 and EP2 and an edge portion of the light-transmissive part TP at each of the plurality of subpixels SP.

The bank layer 170 according to another embodiment of the present disclosure may be formed at only an edge portion of the light-transmissive part TP without covering all of the light-transmissive part TP, in the light-transmissive part TP. For example, the bank layer 170 may be formed at only the edge portion of the light-transmissive part TP except a center portion of the light-transmissive part TP. For example, the bank layer 170 may be formed at only the edge portion of the light-transmissive part TP without being formed at the center portion of the light-transmissive part TP. For example, the bank layer 170 according to another embodiment of the present disclosure may include a structure where the other portion (or the center portion of the light-transmissive part TP), except the edge portion, of the light-transmissive part TP has been removed at the bank layer 170 formed to cover all of the light-transmissive part TP described above with reference to FIGS. 4 to 6. Accordingly, the bank layer 170 disposed at the light-transmissive part TP may include an opening hole (or a light-transmissive hole) overlapping or corresponding to the light-transmissive part TP. For example, the light-transmissive part TP may be defined by the bank layer 170, and may have a size (or area) corresponding to the opening hole of the bank layer 170.

According to another embodiment of the present disclosure, the bank layer 170 may be formed (or configured) to cover only the edge portion of each of the plurality of or first and second emission parts EP1 and EP2. For example, the bank layer 170 may not be formed (or configured) at the light-transmissive part TP, but may be formed (or configured) to cover only the edge portion of each of the plurality of or first and second emission parts EP1 and EP2.

The bank layer 170 according to another embodiment of the present disclosure may include a first bank pattern 171 which is formed to cover the edge portion of the first emission part EP1 at each of the plurality of subpixels SP1 to SP4, a second bank pattern 172 which is formed to cover the edge portion of the second emission part EP2 at each of the plurality of subpixels SP1 to SP4, and a third bank pattern 173 between the plurality of subpixels SP1 to SP4.

The first bank pattern 171 may be formed (or configured) to cover an edge portion of a first pixel electrode PE1 at the first emission part EP1 of each of the plurality of subpixels SP1 to SP4. The second bank pattern 172 may be formed (or configured) to cover an edge portion of a second pixel electrode PE2 at the second emission part EP2 of each of the plurality of subpixels SP1 to SP4. For example, the bank layer 170 may be formed (or configured) to cover the other portion except the center portion of the light-transmissive part TP, the center portion of the first emission part EP1, and the center portion of the second emission part EP2.

The bank layer 170 according to another embodiment of the present disclosure may be formed of an organic material such as benzocyclobutene (BCB)-based resin, acrylic-based resin, or polyimide resin, or the like. For example, the bank layer 170 may be formed of a transparent material and may be a transparent bank, but is not limited thereto. For example, the bank layer 170 may be formed at only the edge portion of the light-transmissive part TP without being formed at all of the light-transmissive part TP, and thus, may be formed (or configured) of a transparent material, a semi-transparent material, or an opaque material. For example, the bank layer 170 may be a transparent bank layer or a black bank layer. For example, the bank layer 170 may be configured in a photosensitizer including a black pigment, in this case, the bank layer 170 may function as a light blocking member disposed between adjacent subpixels SP or adjacent emission parts EP1 and EP2.

According to another embodiment of the present disclosure, the light emitting device ED over the pattern part 150 may be formed (or configured) at the other portion except the center portion of the light-transmissive part TP.

The emission layer EL of the light emitting device ED on the pattern part 150 may be formed to surround the bank layer 170 adjacent to the light-transmissive part TP. For example, a region, corresponding to (or overlapping) the light-transmissive part TP of each of the plurality of subpixels SP1 to SP4, of a region of the emission layer EL may be removed. For example, the emission layer EL may include an opening portion (or an open region or a removal region) which corresponds to (or overlaps) the light-transmissive part TP of each of the plurality of subpixels SP1 to SP4.

The common electrode CE of the light emitting device ED over the pattern part 150 may be formed to surround the emission layer EL surrounding the bank layer 170 adjacent to the light-transmissive part TP. For example, an end of each of the emission layer EL and the common electrode CE of the light emitting device ED adjacent to the light-transmissive part TP may directly contact the first surface 150a of the pattern part 150. For example, a region, corresponding to (or overlapping) the light-transmissive part TP of each of the plurality of subpixels SP1 to SP4, of a region of the common electrode CE may be removed. For example, the common electrode CE may include an opening portion (or an open region or a removal region) which corresponds to (or overlaps) the light-transmissive part TP of each of the plurality of subpixels SP1 to SP4.

According to another embodiment of the present disclosure, the encapsulation part 200 may be formed over the substrate 100 to cover the light emitting device ED. The encapsulation part 200 may be formed over the common electrode CE of the light emitting device ED. For example, the encapsulation part 200 may directly contact the first surface 150a of the pattern part 150 at the light-transmissive part TP of each of the plurality of subpixels SP1 to SP4.

The light emitting display apparatus according to another embodiment of the present disclosure described above with reference to FIGS. 2 and 9 may provide a same effect as that of the light emitting display apparatus according to an embodiment of the present disclosure described above with reference to FIGS. 2 to 6, and the bank layer 170 may not be disposed at the light-transmissive part TP, and thus, a light transmittance of the light-transmissive part TP may increase.

The bank layer 170 described above with reference to FIGS. 2 and 9 may be identically applied to the bank layer 170 described above with reference to FIGS. 7 and 8, and thus, repeated descriptions thereof are omitted. In this case, the bank layer 170 illustrated in FIGS. 7 and 8 may be configured to cover the edge portion of the second pattern layer 155 of the pattern portion 150, and a center portion of the second pattern layer 155 may be covered by the encapsulation part 200. For example, the upper surface 155a of the second pattern layer 155 overlapping the light-transmissive part TP may directly contact the encapsulation part 200.

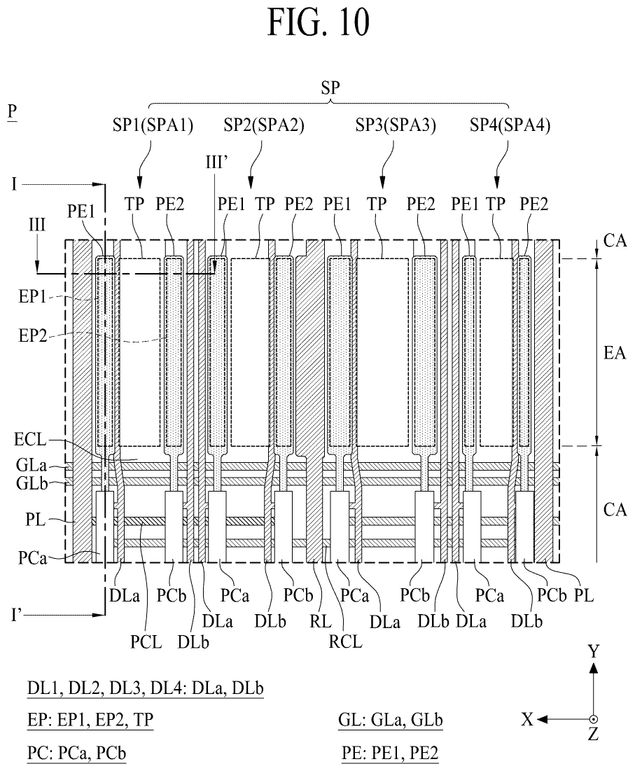

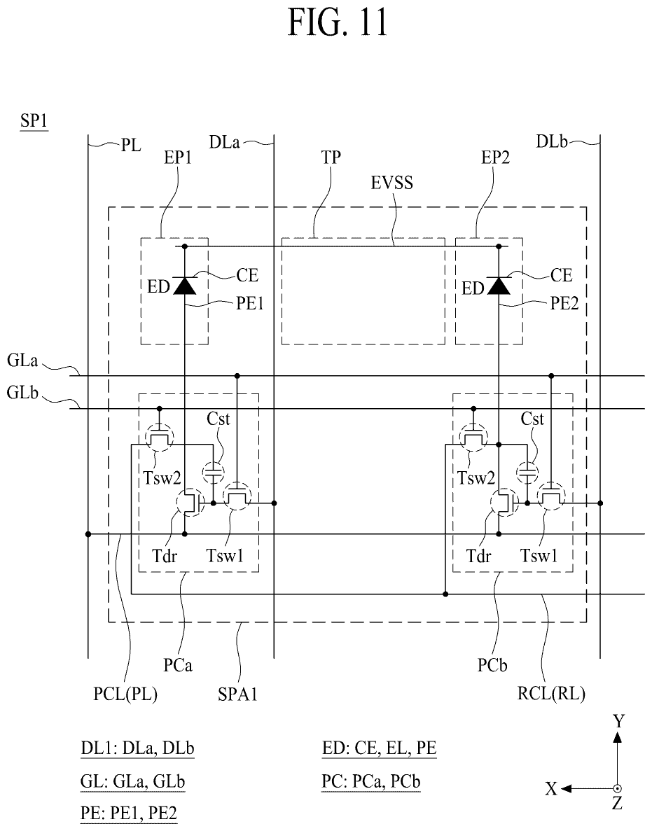

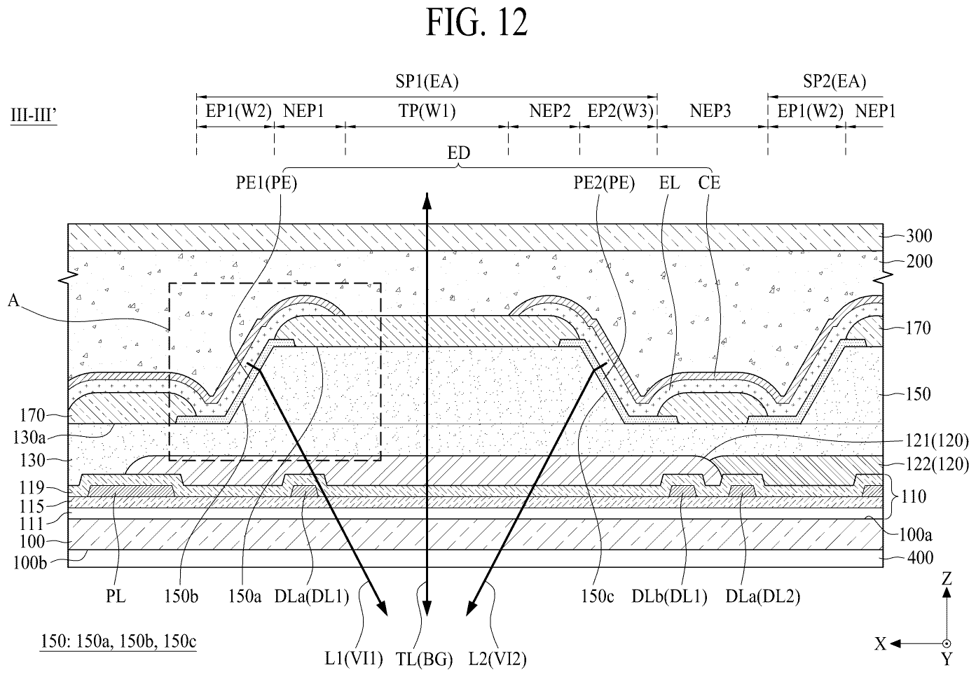

FIG. 10 is a plan view illustrating another example of one pixel illustrated in FIG. 1, FIG. 11 is an equivalent circuit view illustrating a first subpixel illustrated in FIG. 10, and FIG. 12 is an example cross-sectional view taken along line III-III′ illustrated in FIG. 10. An example cross-sectional view of line I-I′ illustrated in FIG. 10 is illustrated in FIG. 4, and an enlarged view of portion ‘A’ illustrated in FIG. 12 is illustrated in FIG. 6. FIGS. 10 to 12 illustrate an embodiment implemented by modifying the data line and the pixel circuit of each of a plurality of subpixels in the light emitting display apparatus (or the light emitting display panel) described above with reference to FIGS. 2 to 6. Therefore, in the following descriptions of FIGS. 10 to 12, the other elements except the data line and the pixel circuit and relevant elements are referred to by like reference numerals, and their repetitive descriptions are omitted. Descriptions of the light emitting display apparatus (or the light emitting display panel) illustrated in FIGS. 2 to 6 may be included in the descriptions of the light emitting display apparatus (or the light emitting display panel) illustrated in FIGS. 10 to 12.

As shown in FIGS. 4 and 10 to 12, the light emitting display apparatus (or the light emitting display panel) according to another embodiment of the present disclosure may be configured to implement (or display) a stereoscopic image, for example, a stereoscopic image through the light field mode (or the light field type). For example, the light emitting display apparatus according to another embodiment of the present disclosure may display a stereoscopic image through the individual light emission of each of a plurality of emission parts EP1 and EP2 configured at each of the plurality of subpixels SP, and thus, may implement (or display) a stereoscopic image (for example, a stereoscopic image based on the light field mode (or the light field type)) or may provide the stereoscopic image to a user (or a viewer).

In the light emitting display apparatus according to another embodiment of the present disclosure, each of a plurality of data lines DL1 to DL4 may include a plurality of sub data lines DLa and DLb respectively corresponding to the plurality of emission parts EP1 and EP2 configured at each of the plurality of subpixels SP. For example, each of first to fourth data lines DL1 to DLA respectively configured at the plurality of subpixels SP may include first and second sub data lines DLa and DLb respectively corresponding to the first and second emission parts EP1 and EP2. For example, the first data line DL1 configured at the first subpixel SP1 may include first and second sub data lines DLa and DLb individually connected to the first and second emission parts EP1 and EP2. For example, each of the plurality of or first to fourth data lines DL1 to DLA may include a number of sub data lines DLa and DLb equal to the number of emission parts EP1 and EP2 configured at one subpixel SP.

The plurality of or first and second sub data lines DLa and DLb may be disposed (or configured) to be electrically disconnected from one another within one subpixel region SPA1 to SPA4.

According to an embodiment of the present disclosure, each of the first and second sub data lines DLa and DLb may be disposed to overlap the bank layer 170 at each of the plurality of subpixels SP. For example, with respect to a thickness direction Z of the substrate 100, in the first and third subpixels SP1 and SP3 (or odd-numbered subpixels), the first sub data line DLa may be disposed to overlap the bank layer 170 covering the edge portion of the first pixel electrode PE1 at the first emission part EP1, and the second sub data line DLb may be disposed to overlap the bank layer 170 covering the edge portion of the second pixel electrode PE2 at the second emission part EP2. For example, with respect to the thickness direction Z of the substrate 100, in the second and fourth subpixels SP2 and SP4 (or even-numbered subpixels), the first sub data line DLa may be disposed to overlap the bank layer 170 covering the edge portion of the first pixel electrode PE1 at the first emission part EP1, and the second sub data line DLb may be disposed to overlap the bank layer 170 covering the edge portion of the second pixel electrode PE2 at the second emission part EP2. For example, the second sub data line DLb at the first and third subpixels SP1 and SP3 may be disposed adjacent to the first sub data line DLa at the second and fourth subpixels SP2 and SP4.

According to another embodiment of the present disclosure, each of the plurality of subpixels SP may include two data lines. Accordingly, each of the plurality of subpixels SP may include a first data line corresponding to the first sub data line DLa and a second data line corresponding to the second sub data line DLb. For example, each of the plurality of subpixels SP may include the first sub data line (or first data line) DLa electrically connected to the first pixel circuit PCa and the second sub data line (or second data line) DLb electrically connected to the second pixel circuit PCb. Therefore, the light emitting display apparatus according to another embodiment of the present disclosure illustrated in FIGS. 10 to 12 may include data lines which are two times more than the number of data lines of the light emitting display apparatus according to an embodiment of the present disclosure illustrated in FIGS. 2 to 6.

In the light emitting display apparatus according to another embodiment of the present disclosure, the pixel circuit PC configured at each of the plurality of subpixels SP may be configured to be individually connected to the plurality of emission parts EP1 and EP2.

The pixel circuit PC according to another embodiment of the present disclosure may include a plurality of pixel circuits PCa and PCb which are individually connected to a plurality of emission parts EP1 and EP2. For example, the pixel circuit PC may include the first and second pixel circuits PCa and PCb which are configured to be individually connected to the first and second emission parts EP1 and EP2.

According to an embodiment of the present disclosure, the pixel circuit PC configured at each of the plurality of subpixels SP1 to SP4 may include the first pixel circuit PCa including a driving TFT Tdr electrically connected to the first pixel electrode PE1 of the first emission part EP1, and the second pixel circuit PCb including a driving TFT Tdr electrically connected to the second pixel electrode PE2 of the second emission part EP2.

According to an embodiment of the present disclosure, each of the first and second pixel electrodes PE1 and PE2 may be spaced apart from (or electrically disconnected from) one another at the emission area EA and the circuit area CA and may be individually connected to the first and second pixel circuits PCa and PCb at the circuit area CA. For example, one end of the first pixel electrode PE1 may extend into the circuit area CA and may be electrically connected to the driving thin film transistor Tdr of the first pixel circuit PCa. One end of the second pixel electrode PE2 may extend into the circuit area CA and may be electrically connected to the driving thin film transistor Tdr of the second pixel circuit PCb.

The first pixel circuit PCa may be electrically connected to the gate line GL, the first sub data line DLa, the driving voltage line PL through the power connection line PCL, and the reference voltage line RL through the reference power connection line RCL. The first pixel circuit PCa may be configured to supply the first pixel electrode PE1 with a first field data current corresponding to a first field data voltage supplied through the first sub data line DLa in response to the gate signal supplied to a corresponding gate line GL. Accordingly, the first emission part EP1 may emit light with the first field data current supplied from the first pixel circuit PCa to the first pixel electrode PE1.

The second pixel circuit PCb may be electrically connected to the gate line GL, the second sub data line DLb, the driving voltage line PL through the power connection line PCL, and the reference voltage line RL through the reference power connection line RCL. The second pixel circuit PCb may be configured to supply the second pixel electrode PE2 with a second field data current corresponding to a second field data voltage supplied through the second sub data line DLb in response to the gate signal supplied to a corresponding gate line GL. Accordingly, the second emission part EP2 may emit light with the second field data current supplied from the second pixel circuit PCb to the second pixel electrode PE2.

According to an embodiment of the present disclosure, each of the first and second pixel circuits PCa and PCb may include a first switching transistor Tsw1, a second switching transistor Tsw2, a driving transistor Tdr, and the storage capacitor Cst. Each of the first and second pixel circuits PCa and PCb may be a same as or substantially a same as the pixel circuit PC described above with reference to FIGS. 3 and 4, and thus, their repetitive descriptions are omitted.

Each of the plurality of gate lines GL may be connected to the first and second pixel circuits PCa and PCb configured at each of the plurality of or first to fourth subpixels SP1 to SP4 in common.

In each of the plurality of or first to fourth data lines DL1 to DLA, the first sub data line DLa may be electrically connected to the first pixel circuit PCa and may supply the first pixel circuit PCa with the first field data voltage provided from the driving IC 35 described above with reference to FIG. 1. The second sub data line DLb may be electrically connected to the second pixel circuit PCb and may supply the second pixel circuit PCb with the second field data voltage provided from the driving IC 35.

According to an embodiment of the present disclosure, the first emission part EP1 may display a first viewing angle image VI1 corresponding to the first field data voltage, and the second emission part EP2 may display a second viewing angle image VI2 corresponding to the second field data voltage. For example, when the light emitting display apparatus is in the normal driving mode, the first and second viewing angle images VI1 and VI2 respectively displayed by the first and second emission parts EP1 and EP2 may be equal to one another, and in this case, a viewing angle may increase or enlarge. For example, when the light emitting display apparatus is in the light field driving mode (or the stereoscopic image display mode), the first and second viewing angle images VI1 and VI2 respectively displayed by the first and second emission parts EP1 and EP2 may differ, and thus, a stereoscopic image of the light field mode may be implemented by each of the first and second viewing angle images VI1 and VI2. For example, the first viewing angle image VI1 may be a first side image, a first side viewing angle image, a right-eye image, or a first viewer image. The second viewing angle image VI2 may be a second side image, a second side viewing angle image, a left-eye image, or a second viewer image.

The light emitting display apparatus according to another embodiment of the present disclosure described above with reference to FIGS. 10 to 12 may provide the same effect as that of the light emitting display apparatus according to an embodiment of the present disclosure described above with reference to FIGS. 2 to 6 and may implement (or display) a stereoscopic image (for example, a stereoscopic image of the light field mode) by using an image displayed by each of a plurality of emission parts.

According to another embodiment of the present disclosure, the pattern part 150 described above with reference to FIG. 7 may be applied to the pattern part 150 of the light emitting display apparatus according to another embodiment of the present disclosure described above with reference to FIGS. 10 to 12. For example, the pattern part 150 illustrated in FIG. 12 may include the first pattern layer 151, the groove part 153, and the second pattern layer 155 described above with reference to FIG. 7, and thus, their repetitive descriptions are omitted.

According to another embodiment of the present disclosure, the pattern part 150 described above with reference to FIGS. 7 and 8 may be applied to the pattern part 150 of the light emitting display apparatus according to another embodiment of the present disclosure described above with reference to FIGS. 10 to 12. For example, the pattern part 150 illustrated in FIG. 12 may include the first pattern layer 151, the groove part 153, and the second pattern layer 155 described above with reference to FIGS. 7 and 8, and thus, their repetitive descriptions are omitted.

According to another embodiment of the present disclosure, the bank layer 170 described above with reference to FIG. 9 may be applied to the bank layer 170 of the light emitting display apparatus according to another embodiment of the present disclosure described above with reference to FIGS. 10 to 12. For example, the bank layer 170 illustrated in FIG. 12 may not be disposed (or configured) at the light-transmissive part TP described above with reference to FIG. 9, and thus, repeated descriptions thereof are omitted.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various modifications and variations may be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A light emitting display apparatus, comprising:
a substrate; and
a plurality of pixels each including a plurality of subpixels on the substrate,
wherein each of the plurality of subpixels comprises:
a light-transmissive part;
a first emission part at a first side of the light-transmissive part; and
a second emission part at a second side of the light-transmissive part different from the first side of the light-transmissive part, and
wherein each of the first emission part and the second emission part is inclined from the light-transmissive part.

2. The light emitting display apparatus of claim 1, wherein:
the second emission part is at the second side of the light-transmissive part which is opposite to the first side of the light-transmissive part, and
each of the first emission part and the second emission part is configured to be inclined with respect to the substrate.

3. The light emitting display apparatus of claim 1,
wherein each of the plurality of subpixels further comprises:
a pixel circuit connected to the first emission part and the second emission part;
a protection layer covering the pixel circuit;
a pattern part over the protection layer; and
a light emitting device over the pattern part, and
wherein the first emission part and the second emission part are configured at the pattern part.

4. The light emitting display apparatus of claim 3, wherein:
the pattern part comprises an upper surface, a first slope surface at a first side of the upper surface, and a second slope surface at a second side different from the first side of the upper surface;
the light-transmissive part is at the upper surface of the pattern part;
the first emission part is at the first slope surface of the pattern part; and
the second emission part is at the second slope surface of the pattern part.

5. The light emitting display apparatus of claim 4, wherein the light emitting device comprises:
a first pixel electrode at the first slope surface of the pattern part;
a second pixel electrode at the second slope surface of the pattern part;
an emission layer over the first pixel electrode and the second pixel electrode; and
a common electrode over the emission layer.

6. The light emitting display apparatus of claim 5, further comprising:
a plurality of gate lines connected to the pixel circuit of each of the plurality of subpixels in common; and
a plurality of data lines disposed at each of the plurality of subpixels and connected to the pixel circuit,
wherein the pixel circuit comprises a driving thin film transistor connected to the first and second pixel electrodes in common.

7. The light emitting display apparatus of claim 5, wherein the pixel circuit of each of the plurality of subpixels comprises:
a first pixel circuit including a driving thin film transistor electrically connected to the first pixel electrode; and
a second pixel circuit including a driving thin film transistor electrically connected to the second pixel electrode.

8. The light emitting display apparatus of claim 7, further comprising a gate line commonly connected to the first and second pixel circuits disposed at each of the plurality of subpixels,
wherein each of the plurality of subpixels further comprises:
a first data line electrically connected to the first pixel circuit; and
a second data line electrically connected to the second pixel circuit.

9. The light emitting display apparatus of claim 4, wherein:
the upper surface of the pattern part comprises a flat surface, and/or
an angle between an upper surface of the protection layer and each of the first slope surface and the second slope surface of the pattern part is an acute angle.

10. The light emitting display apparatus of claim 4,
wherein the pattern part comprises:
a first pattern layer over the protection layer;
a groove portion at the first pattern layer and overlapping the light-transmissive part; and
a second pattern layer at the groove portion,
wherein the upper surface of the pattern part comprises an upper side surface of the first pattern layer and an upper side surface of the second pattern layer, and
wherein the first pattern layer comprises the first slope surface and the second slope surface.

11. The light emitting display apparatus of claim 10, wherein:
the first pattern layer and the second pattern layer have different refractive indexes, or
a refractive index of the second pattern layer is lower than a refractive index of the first pattern layer.

12. The light emitting display apparatus of claim 10, wherein the groove portion comprises a slope surface or a curved surface.

13. The light emitting display apparatus of claim 1, wherein:
the first emission part displays a first viewing angle image,
the second emission part displays a second viewing angle image, and
the first viewing angle image and the second viewing angle image are equal to one another or different from one another.

14. A light emitting display apparatus, comprising:
a substrate; and
a plurality of pixels including a plurality of subpixels over the substrate,
wherein each of the plurality of subpixels comprises:
a light-transmissive part; and
a plurality of emission part disposed adjacent to the light-transmissive part and inclined with respect to the substrate.

15. The light emitting display apparatus of claim 14,
wherein the plurality of emission part comprises:
a first slope emission part at a first side of the light-transmissive part; and
a second slope emission part at a second side of the light-transmissive part different from the first side of the light-transmissive part, and
wherein each of the first slope emission part and the second slope emission part is inclined with respect to the substrate.

16. The light emitting display apparatus of claim 15,
wherein each of the plurality of subpixels further comprises:
a pixel circuit connected to the first slope emission part and the second slope emission part;
a protection layer covering the pixel circuit;
a pattern part over the protection layer; and
a light emitting device over the pattern part, and
wherein the first slope emission part and the second slope emission part are configured at the pattern part.

17. The light emitting display apparatus of claim 16, wherein:
the pattern part comprises an upper surface, a first slope surface at a first side of the upper surface, and a second slope surface at a second side different from the first side of the upper surface;
the light-transmissive part is at the upper surface of the pattern part;
the first slope emission part is at the first slope surface of the pattern part; and
the second slope emission part is at the second slope surface of the pattern part.

18. The light emitting display apparatus of claim 17, wherein the light emitting device comprises:
a first pixel electrode at the first slope surface of the pattern part;
a second pixel electrode at the second slope surface of the pattern part;
an emission layer over the first and second pixel electrodes; and
a common electrode over the emission layer.

19. The light emitting display apparatus of claim 18, further comprising:
a gate line connected to the pixel circuit of each of the plurality of subpixels in common; and
a plurality of data lines disposed at each of the plurality of subpixels and connected to the pixel circuit,
wherein the pixel circuit comprises a driving thin film transistor connected to the first and second pixel electrodes in common.

20. The light emitting display apparatus of claim 18, further comprising a gate line connected to the pixel circuit of each of the plurality of subpixels,
wherein the pixel circuit comprises:
a first pixel circuit including a driving thin film transistor electrically connected to the first pixel electrode; and
a second pixel circuit including a driving thin film transistor electrically connected to the second pixel electrode,
wherein each of the plurality of subpixels further comprises:
a first data line electrically connected to the first pixel circuit; and
a second data line electrically connected to the second pixel circuit, and
wherein the gate line is connected to the first and second pixel circuits of each of the plurality of subpixels in common.

21. The light emitting display apparatus of claim 14, further comprising:
a bank layer covering an edge portion of the emission part and an entire emission part, or
a bank layer covering an edge portion of the emission part and an edge portion of the light-transmissive part.

22. A light emitting display apparatus, comprising:
a substrate; and
a plurality of pixels each including a plurality of subpixels on the substrate,
wherein each of the plurality of subpixels comprises:
a light-transmissive part;
a first emission part at a first side of the light-transmissive part;
a second emission part at a second side of the light-transmissive part different from the first side of the light-transmissive part, and
a pattern part disposed in an emission area of the subpixel,
wherein the pattern part comprises an upper surface, a first slope surface at a first side of the upper surface, and a second slope surface at a second side different from the first side of the upper surface,
wherein the light-transmissive part is at the upper surface of the pattern part,
wherein the first emission part is at the first slope surface of the pattern part,
wherein the second emission part is at the second slope surface of the pattern part, and
wherein each of the first emission part and the second emission part is inclined from the light-transmissive part.
